(19) United States
(12) Patent Application Publication
(10) Pub. No.: US 2025/0078735 A1
(43) Pub. Date: Mar. 6, 2025

(54) DISPLAY DEVICE

(71) Applicant: LG Display Co., Ltd., Seoul (KR)

(72) Inventors: Hyunguk JANG, Seoul (KR); EuiHyun CHUNG, Seoul (KR); JoungMi CHOI, Gimpo-si (KR)

(73) Assignee: LG Display Co., Ltd., Seoul (KR)

(21) Appl. No.: 18/807,274

(22) Filed: Aug. 16, 2024

(30) Foreign Application Priority Data
Aug. 31, 2023 (KR) 10-2023-0115320

(51) Int. Cl. G09G 3/32; G09G 3/3266; G09G 3/3275

(52) U.S. Cl. CPC G09G 3/32; G09G 3/3266; G09G 3/3275; G09G 2310/0267; G09G 2310/0275; G09G 2320/0233; G09G 2320/0247

(57) ABSTRACT

A display device may include a display panel including a plurality of pixels; and a data driver circuit configured to supply a data signal to the plurality of the pixels through data lines. A gate driver circuit, configured to supply a gate signal to the plurality of the pixels through gate lines, is disposed in the display panel. The display panel includes a driving layer including a gate area having the gate driver circuit; and a pixel circuit layer including an active area having a pixel area in which each of the plurality of pixels is disposed and a non-active area around the active area. The pixel circuit layer includes a light emitting diode, a clock line configured to supply a clock signal to the gate driver circuit, and a shielding pattern between the light emitting diode and the clock line.

### CROSS-REFERENCE TO RELATED APPLICATIONS

This application claims the priority of Korean Patent Application No. 10-2023-0115320 filed on Aug. 31, 2023, in the Korean Intellectual Property Office, the disclosure of which is incorporated herein by reference.

### BACKGROUND

### Technical Field

The present disclosure relates to a display device.

### Discussion of the Related Art

As it enters an information era, a display field which visually expresses electrical

information signals has been rapidly developed, and in response to this, various display devices having excellent performances such as thin-thickness, light weight, and low power consumption have been developed. Examples of such a display device may include a liquid crystal display (LCD) device, an organic light emitting display (OLED) device, and the like.

Such a display device may include a display panel in which pixels for displaying images are disposed and a driving circuit. The driving circuit includes a data driver configured to supply a data signal to the pixels through data lines, a gate driver configured to supply a gate signal to the pixels through gate lines, and a timing controller which controls the data driver and the gate driver.

### SUMMARY

Accordingly, embodiments of the present disclosure are directed to a display device that substantially obviates one or more of the problems due to limitations and disadvantages of the related art.

An aspect of the present disclosure is to provide a display device that minimizes or at least reduces a bezel area.

Another aspect of the present disclosure is to provide a display device which is implemented to have a high resolution and a large area.

Still another aspect of the present disclosure is to provide a display device in which an interval between each signal line and/or a power line connected to a pixel is minimized or at least reduced, and a design easiness is ensured.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a display panel including a plurality of pixels; and a data driver circuit configured to supply a data signal to the plurality of the pixels through data lines, wherein a gate driver circuit, configured to supply a gate signal to the plurality of the pixels through gate lines, is disposed in the display panel, wherein the display panel includes a driving layer including a gate area having the gate driver circuit; and a pixel circuit layer including an active area having a pixel area in which each of the plurality of pixels is disposed and a non-active area around the active area, and wherein the pixel circuit layer includes a light emitting diode, a clock line configured to supply a clock signal to the gate driver circuit, and a shielding pattern between the light emitting diode and the clock line.

Other detailed matters of the example embodiments are included in the detailed description and the drawings.

In the display device according to the example embodiments of the present disclosure, a display panel may include a pixel circuit layer in which a pixel is disposed and a driving layer in which a gate driver is disposed. Here, a gate area in which various elements configuring the gate driver are disposed may be disposed to overlap at least a part of an active area in which various elements configuring the pixel are disposed. For example, transistors included in the driving layer may be disposed on the same layer as at least some of the transistors included in the pixel circuit layer. For example, the gate driver is disposed and formed on a gate area overlapping the active area, on the same layer as the pixel circuit layer in which a pixel is disposed, in a gate in array (GIA) manner so that a bezel area of the display device may be minimized or at least reduced.

As compared with the gate in panel (GIP) manner in which the gate driver is formed at the outside of the active area to supply a gate signal to the pixels, in the display device according to the example embodiments of the present disclosure, the gate driver is disposed in at least partial area of the active area, for example, on the gate area, in the gate in array (GIA) manner. Therefore, the gate signal delay according to the relative position of the pixel is minimized or at least reduced to improve the luminance uniformity of the entire active area so that the display device with a high resolution and a large area can be implemented at a low power.

Further, in the display device according to the example embodiments of the present disclosure, a seventh conductive layer disposed above the second planarization layer is disposed in a part of a fifth conductive layer which configures a clock line supplying a clock signal to the gate driver and an anode electrode of the light emitting diode to perform a function as a shielding pattern which shields a signal. Therefore, a display quality may be improved.

Further, a pixel included in the display device according to the example embodiments of the present disclosure has a vertical flip structure. Therefore, a space for disposing a transistor, a capacitor, and the like which configure the gate driver may be ensured on the gate area of the driving layer which overlaps a center area of the pixel circuit layer.

Further, in the display device according to the example embodiments of the present disclosure, a third power line, a second scan line, and an emission line which are included in a first conductive layer and a fourth scan line, a first scan line, and a third scan line included in a fourth conductive layer which is formed of a different metal material from the first conductive layer are alternately disposed along one direction (a second direction). Therefore, an interval between each signal line and/or a power line may be minimized or at least reduced. Accordingly, a design easiness may be ensured.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a block diagram illustrating a display device according to example embodiments of the present disclosure;

FIG. 2A is a view illustrating an example of a gate driver included in a display device of FIG. 1;

FIG. 2B is a view illustrating another example of a gate driver included in a display device of FIG. 1;

FIG. 3 is a circuit diagram illustrating an example of a gate driver included in a display device of FIG. 1;

FIG. 4 is a circuit diagram illustrating an example of a pixel included in a display device of FIG. 1;

FIG. 5 is a plan view illustrating a display device according to example embodiments of the present disclosure;

FIG. 6A is a view for explaining an example of an active area and a gate area included in a display device of FIG. 5;

FIG. 6B is a view for explaining another example of an active area and a gate area included in a display device of FIG. 5;

FIG. 7 is a cross-sectional view schematically illustrating an example of a display panel included in a display device of FIG. 5;

FIG. 8 is a cross-sectional view illustrating an example of a display panel of FIG. 7;

FIG. 9 is a layout illustrating an example of a pixel included in a display device of FIG. 5; and

FIG. 10 is a cross-sectional view illustrating an example taken along the line I-I′ of FIG. 9.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

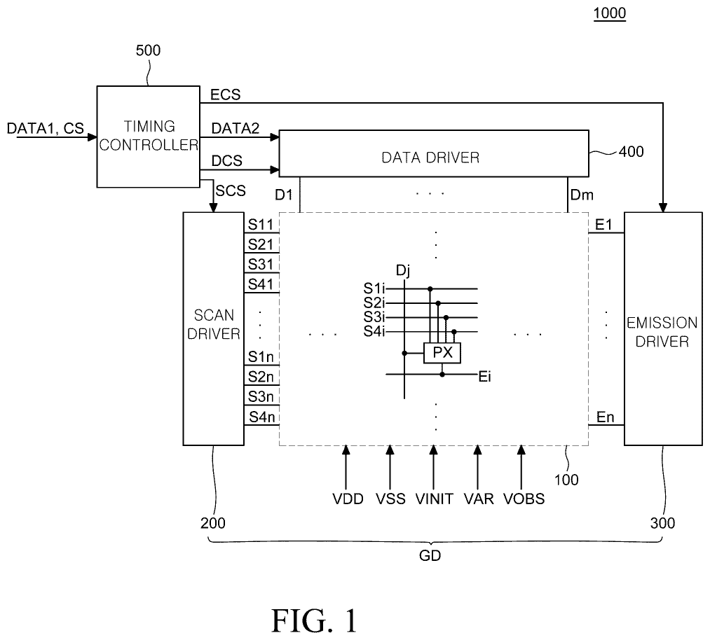

FIG. 1 is a block diagram illustrating a display device according to example embodiments of the present disclosure.

With reference to FIG. 1, a display device 1000 according to example embodiments of the present disclosure may include a pixel unit 100, a gate driver GD (e.g., gate driver circuit), a data driver 400 (e.g., data driver circuit), and a timing controller 500. In one example embodiment, a gate driver GD may include a scan driver 200 and an emission driver 300.

The display device 1000 may display images at various frame frequencies (a refresh rate, a driving frequency, or a screen refresh rate) depending on a driving condition. The frame frequency is a frequency at which a data voltage is actually written in a driving transistor of a pixel PX for one second. For example, the frame frequency is also referred to as a screen scan rate or a screen refresh frequency and indicates a frequency at which the display screen is refreshed for one second.

In one example embodiment, an output frequency of a scan signal (for example, a second scan signal) that is supplied to a scan line (for example, the second scan line) to supply a data signal output frequency and/or a data signal of the data driver 400 may be changed in response to the frame frequency. For example, when the frame frequency is 120 Hz, the second signal may be supplied to each horizontal line (a pixel row) 120 times per second.

In one example embodiment, the display device 1000 may adjust output frequencies of the scan driver 200 and the emission driver 300 and an output frequency of the data driver 400 corresponding thereto in accordance with the driving condition. For example, the display device 1000 may display images in accordance with various frame frequencies of 1 Hz to 120 Hz. Here, the frame frequency may be set by a divisor of a maximum frequency excluding the maximum frequency based on the maximum frequency at which the scan signal is supplied. For example, the scan signal may be supplied at a maximum of 240 Hz, and accordingly, the display device 1000 may display images at frame frequencies corresponding to divisors of 240 Hz, excluding 240 Hz. However, this is illustrative and the display device 1000 may display images also at a frame frequency (for example, 240 Hz or 480 Hz) that is 120 Hz or higher.

In the meantime, the display device 1000 may operate at various frame frequencies. In the case of the low-frequency driving, image defects such as flicker may be visible due to the current leakage in the pixel. Further, after-images such as image drag may be visible due to a bias state change of the driving transistor due to the driving at various frame frequencies or change in the response speed due to a threshold voltage shift, etc. caused by changes in hysteresis characteristic.

To improve an image quality, one frame period may include a plurality of non-emission periods and emission periods according to the frame frequency. For example, first non-emission period and emission period of one frame may be defined as a first driving period and subsequent non-emission period and emission period may be defined as a second driving period. For example, in the first driving period, a data signal for substantially displaying images may be written in the pixel PX in the first driving period and an on-bias may be applied to the driving transistor of the pixel PX in the second driving period.

The pixel unit 100 may include scan lines S11 to S1n, S21 to S2n, S31 to S3n, and S41 to S4n, emission control lines E1 to En, and data lines D1 to Dm and include pixels PX connected to the scan lines S11 to S1n, S21 to S2n, S31 to S3n, and S41 to S4n, the emission control lines E1 to En, and the data lines D1 to Dm (where m and n are integers larger than 0). Each pixel PX may include a driving transistor and a plurality of switching transistors.

A pixel PX disposed in an i-th row and a j-th column, among pixels PX, may be connected to a corresponding first scan line (for example, an i-th first scan line S1i), among first scan lines S11 to S1n, a corresponding second scan line (for example, an i-th second scan line S2i), among second scan lines S21 to S2n, a corresponding third scan line (for example, an i-th third scan line S3i), among third scan lines S31 to S3n, a corresponding fourth scan line (for example, an i-th fourth scan line S4i), among fourth scan lines S41 to S4n, a corresponding emission control line (for example, an i-th emission control line Ei), among emission control lines E1 to En, and a corresponding data line (for example, a j-th data line Dj), among data lines D1 to Dm (where i and j are integers that are larger than 0).

The pixels PX may be supplied with a first power voltage VDD, a second power voltage VSS, a third power voltage VINIT (for example, a first initialization voltage), a fourth power voltage VAR (for example, a second initialization voltage), and a fifth power voltage VOBS (for example, a bias voltage).

A voltage level of the second power voltage VSS may be lower than a voltage level of the first power voltage VDD. For example, the first power voltage VDD may be a positive voltage and the second power voltage VSS may be a negative voltage.

The third power voltage VINIT (for example, first initialization voltage) and the fourth power voltage VAR (for example, second initialization voltage) are initialization voltages that initialize the pixel PX and for example, the driving transistor and/or the light emitting diode included in the pixel PX may be initialized by the initialization voltage.

The fifth power voltage VOBS (for example, bias voltage) may be a voltage for supplying a predetermined bias to the source electrode and/or the drain electrode of the driving transistor included in the pixel PX. For example, the fifth power voltage VOBS may be a positive voltage. However, a voltage level of the fifth power voltage VOBS is not limited thereto and the fifth power voltage VOBS may be set as a negative voltage. In the example embodiments of the present disclosure, signal lines connected to the pixel PX may be set in various forms in accordance with a circuit structure of the pixel PX.

The timing controller 500 may be supplied with first data DATA1 (for example, input image data) and an input control signal CS from a host system through a predetermined interface. The timing controller 500 may control driving timings of the scan driver 200, the emission driver 300, and the data driver 400.

The timing controller 500 may generate a first control signal SCS, a second control signal ECS, and a third control signal DCS based on the first data DATA1 and the input control signal CS. For example, the input control signal CS may include a vertical synchronization signal, a horizontal synchronization signal, a data enable signal, and a clock signal. The first control signal SCS may be supplied to the scan driver 200, the second control signal ECS may be supplied to the emission driver 300, and the third control signal DCS may be supplied to the data driver 400. The timing controller 500 realigns the first data DATA1 to generate the second data DATA2 and supply the second data to the data driver 400.

The scan driver 200 receives a first control signal SCS (for example, a scan control signal) from the timing controller 500. The scan driver 200 may supply a first scan signal, a second scan signal, a third scan signal, and a fourth scan signal to the first scan lines S11 to S1n, the second scan lines S21 to S2n, the third scan lines S31 to S3n, and the fourth scan lines S41 to S4n based on the first control signal SCS, respectively.

The first to fourth scan signals may be set as a gate-on voltage (for example, a low voltage or a high voltage) corresponding to a type of a transistor to which the corresponding scan signals are supplied. The transistor that receives the scan signal may be set to a turn-on state when the scan signal is supplied. For example, a gate-on voltage of a scan signal supplied to a P-channel metal oxide semiconductor (PMOS) transistor may be a logic low level and a gate-on voltage of a scan signal supplied to an N-channel metal oxide semiconductor (NMOS) transistor may be a logic high level. Hereinafter, the meaning of “scan signal is supplied” is understood that the scan signal is supplied at a logic level that turns on the transistor that is controlled by the scan signal.

The emission driver 300 may supply an emission control signal to emission control lines E1 to En based on a second control signal ECS (for example, an emission driving control signal). For example, the emission control signal may be sequentially supplied to the emission control lines E1 to En.

The emission control signal may be set as a gate-off voltage (for example, a high voltage). A transistor that receives the emission control signal may be turned off when the emission control signal is supplied and may be set to be in a turn-on state, in the other cases. Hereinafter, the meaning of “emission control signal is supplied” is understood that the emission control signal is supplied at a logic level that turns off the transistor that is controlled by the emission control signal.

In the meantime, for the convenience of description, in FIG. 1, it is illustrated that the scan driver 200 and the emission driver 300 are single configurations, respectively, but the present disclosure is not limited thereto. Depending on the design, the scan driver 200 may include a plurality of scan drivers configured to supply at least one of the first to fourth scan signals, respectively. Further, at least some of the scan driver 200 and the emission driver 300 may be integrated as one driving circuit or module.

The data driver 400 may receive a third control signal DCS (for example, a data control signal) and a second data DATA2 (for example, image data) from the timing controller 500. The data driver 400 may convert a digital type of second data DATA2 into an analog data signal (for example, a data voltage). The data driver 400 may supply the data signal to the data lines D1 to Dm in response to the third control signal DCS. At this time, the data signal supplied to the data lines D1 to Dm may be supplied to be synchronized with the second scan signal supplied to the second scan lines S21 to S2n.

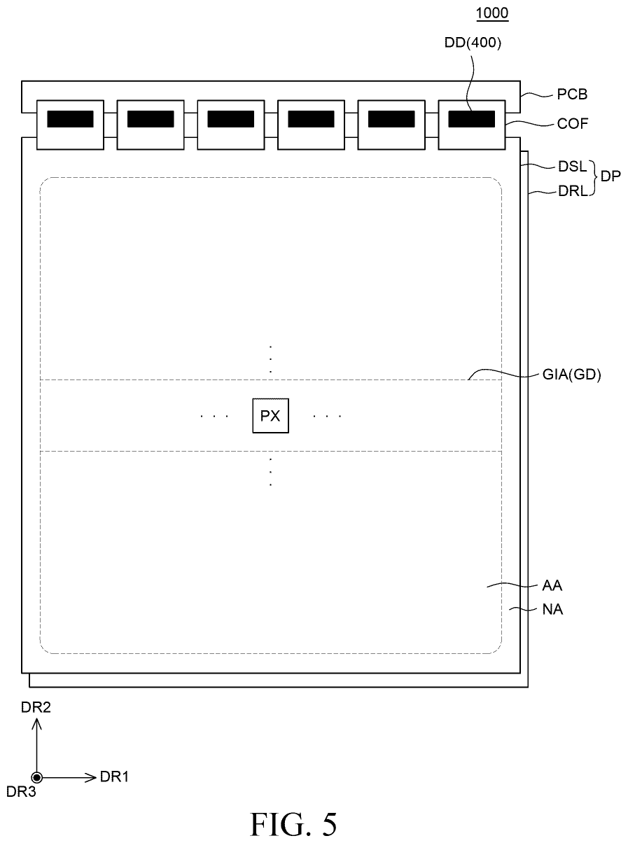

In the meantime, the normal gate driver is formed independently from the display panel to be electrically connected to the display panel in various manners. However, in the display device according to the example embodiments of the present disclosure, the gate driver GD, for example, the scan driver 200 and the emission driver 300 are formed in the form of thin film pattern during the manufacturing of a substrate of a display panel to be formed on at least a partial area (for example, a gate area GIA (see FIG. 5)) of the active area AA (see FIG. 5) of the display panel in a gate in array manner.

This will be described below in more detail with reference to FIGS. 1 to 5.

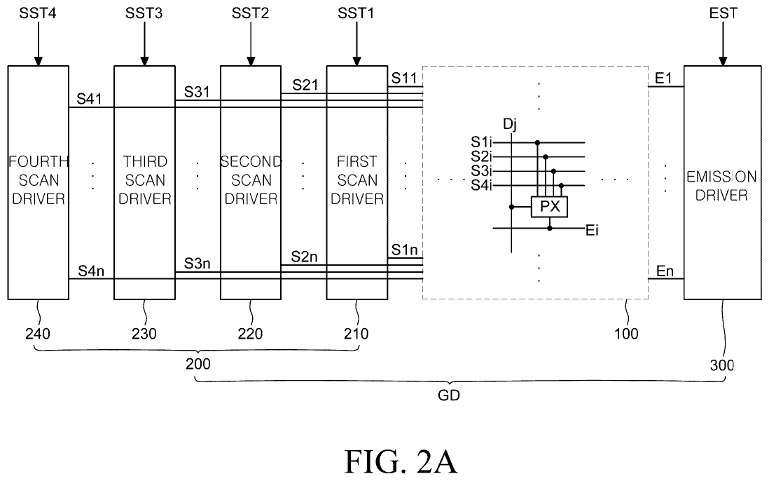

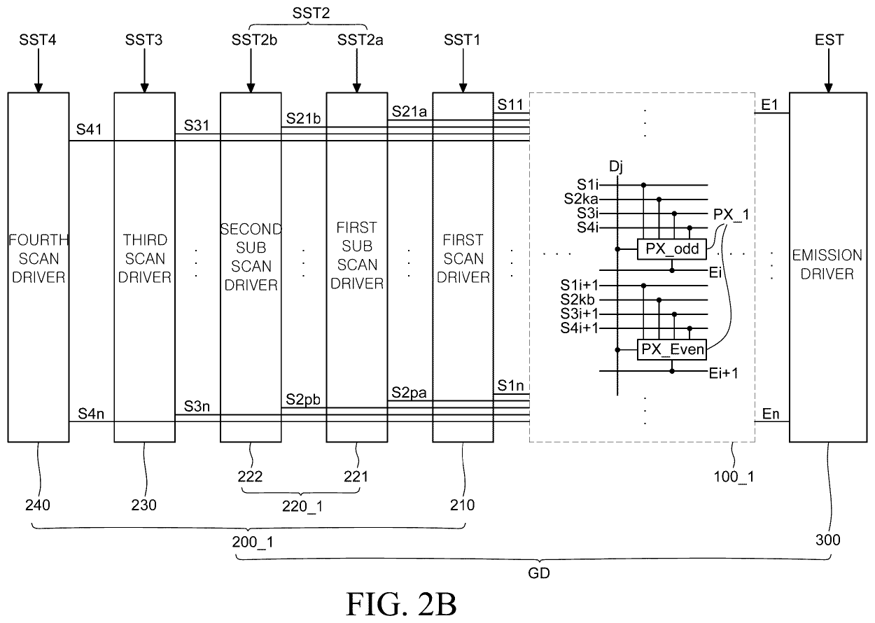

FIG. 2A is a view illustrating an example of a gate driver included in a display device of FIG. 1. FIG. 2B is a view illustrating another example of a gate driver included in a display device of FIG. 1.

With reference to FIGS. 1 and 2A, the gate driver GD may include a scan driver 200 and an emission driver 300 and the scan driver 200 may include a first scan driver 210, a second scan driver 220, a third scan driver 230, and a fourth scan driver 240. The first control signal SCS (for example, a scan control signal) may include first to fourth scan start signals SST1 to SST4. The first to fourth scan start signals SST1 to SST4 may be supplied to first to fourth scan drivers 210, 220, 230, and 240, respectively.

Widths and supply timings of the first to fourth scan start signals SST1 to SST4 may be determined according to a driving condition and a frame frequency of the pixel PX. The first to fourth scan signals may be output based on the first to fourth scan start signals SST1 to SST4. For example, a signal width of at least one of the first to fourth scan signals may be different from a signal width of the others.

The first scan driver 210 may sequentially supply the first scan signal to the first scan lines S11 to S1n in response to the first scan start signal SST1. The second scan driver 220 may sequentially supply the second scan signal to the second scan lines S21 to S2n in response to the second scan start signal SST2. The third scan driver 230 may sequentially supply the third scan signal to the third scan lines S31 to S3n in response to the third scan start signal SST3. The fourth scan driver 240 may sequentially supply the fourth scan signal to the fourth scan lines S41 to S4n in response to the fourth scan start signal SST4.

Further, the second control signal ECS (for example, an emission driving control signal) may include an emission start signal EST. The emission start signal EST may be supplied to the emission driver 300.

A width and a supply timing of the emission start signal EST may be determined according to a driving condition and a frame frequency of the pixel PX. The emission signal may be output based on the emission start signal EST. The emission driver 300 may sequentially supply the emission signal to the emission control lines E1 to En in response to the emission start signal EST.

In the meantime, even though in FIG. 2A, it is illustrated that one second scan driver 220 supplies second scan signals through second scan lines S21 to S2n that are connected to the respective pixels PX disposed in all rows (or all horizontal lines), the example embodiments of the present disclosure are not limited thereto.

For example, with reference to FIG. 2B, pixels PX_1 included in the pixel unit 100_1 are divided into pixels PX_Odd disposed in odd-numbered rows, for example, i-th rows and pixels PX_Even disposed in even-numbered rows, for example, i+1-th rows (where i is an odd-numbered natural number).

Here, a pixel PX_Odd that is disposed in a j-th column, among pixels PX_Odd disposed in the odd-numbered row, for example, the i-th row, may be connected to a corresponding first scan line (for example, an i-th first scan line S1i), among first scan lines S11 to S1n, a corresponding first sub scan line (for example, a k-th first sub scan S2ka), among first sub scan lines S21a to Spa, as a second scan line, a corresponding third scan line (for example, an i-th third scan line S3i), among third scan lines S31 to S3n, a corresponding fourth scan line (for example, an i-th fourth scan line S4i), among fourth scan lines S41 to S4n, a corresponding emission control line (for example, an i-th emission control line Ei), among emission control lines E1 to En, and a corresponding data line (for example, a j-th data line Dj), among data lines D1 to Dm (in this case, 2p is n and 2k is i+1).

Further, a pixel PX_Even that is disposed in a j-th column, among pixels PX_Even disposed in the even-numbered row, for example, the i+1-th row, may be connected to a corresponding first scan line (for example, an i+1-th first scan line S1i+1), among first scan lines S11 to S1n, a corresponding second sub scan line (for example, a k-th second sub scan line S2kb), among second sub scan lines S21b to S2pb, as a second scan line, a corresponding third scan line (for example, an i+1-th third scan line S3i+1), among third scan lines S31 to S3n, a corresponding fourth scan line (for example, an i+1-th fourth scan line S4i+1), among fourth scan lines S41 to S4n, a corresponding emission control line (for example, an i+1-th emission control line Ei+1), among emission control lines E1 to En, and a corresponding data line (for example, a j-th data line Dj), among data lines D1 to Dm.

The first control signal SCS (for example, a scan control signal) may include first to fourth scan start signals SST1, SST2_1, SST3, and SST4. The first to fourth scan start signals SST1, SST2_1, SST3, and SST4 may be supplied to first to fourth scan drivers 210, 220_1, 230, and 240, respectively. In the meantime, the second scan start signal SST2_1 may include a first sub scan start signal SST2a and a second sub scan start signal SST2b.

The gate driver GD_1 may include a scan driver 200_1 and an emission driver 300 and the scan driver 200_1 may include a first scan driver 210, a second scan driver 220_1, a third scan driver 230, and a fourth scan driver 240. In one example embodiment, the second scan driver 220_1 may include a first sub scan driver 221 and a second sub scan driver 222.

The first sub scan driver 221 of the second scan driver 220 may sequentially supply a first sub scan signal to the first sub scan lines S21a to S2pa in response to a first sub scan start signal SST2a. Further, the second sub scan driver 222 of the second scan driver 220 may sequentially supply a second sub scan signal to the second sub scan lines S21b to S2pb in response to a second sub scan start signal SST2b.

As described above, in the display device 1000 according to the example embodiments of the present disclosure, the second scan driver 220_1 included in the scan driver 200_1 may also be configured to be divided into a first sub scan driver 221 and a second sub scan driver 222. The first sub scan driver 221 supplies second scan signals (for example, first sub scan signals) to pixels PX_Odd disposed in odd-numbered rows and the second sub scan driver 222 supplies second scan signals (for example, second sub scan signals) to pixels PX_Even disposed in even-numbered rows.

In the meantime, hereinafter, for the convenience of description, unless otherwise mentioned, the description will be based on one second scan driver 220 supplying second scan signals via second scan lines S21 to S2n that are connected to each of the pixels PX disposed in every row (or every horizontal line), as illustrated in FIG. 2A.

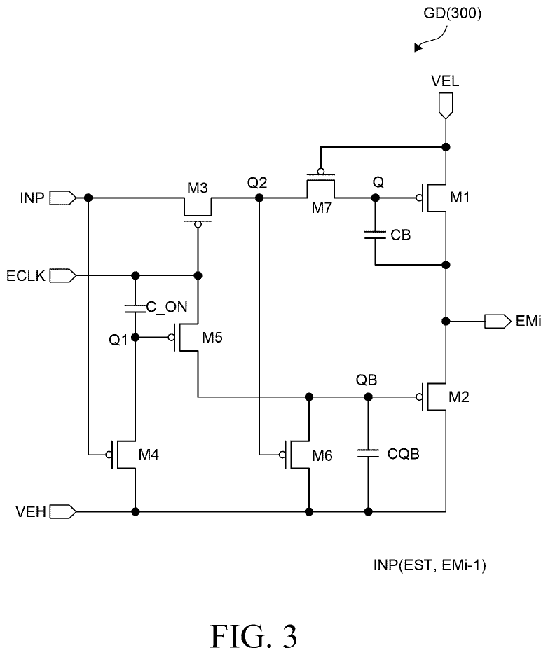

FIG. 3 is a circuit diagram illustrating an example of a gate driver included in a display device of FIG. 1.

In the meantime, FIG. 3 illustrates a circuit diagram illustrating an example of an emission stage configured to supply an emission control signal (for example, an i-th emission control signal EMi) to pixels PX disposed in an i-th row, among emission stages included in the emission driver 300 between the scan driver 200 and the emission driver 300 included in the gate driver GD.

With reference to FIGS. 1 and 3, the emission stage included in the emission driver 300 may receive an input signal INP (for example, an emission start signal EST or a previous emission control signal (for example, a i-1-th emission control signal EMi-1)) and an emission clock signal ECLK. The emission stage may receive a first driving power voltage VEH and a second driving power voltage VEL.

A voltage level of a second driving power voltage VEL may be lower than a voltage level of the first driving power voltage VEH. For example, the first driving power voltage VEH may be a positive voltage and the second driving power voltage VEL may be a negative voltage, but these are illustrative and the example embodiments of the present disclosure are not limited thereto.

In one example embodiment, the emission stage may generate and output an i-th emission control signal EMi based on an input signal INP, an emission clock signal ECLK, a first driving power voltage VEH, and a second driving power voltage VEL.

To this end, the emission stage may include first to seventh stage transistors M1 to M7, a first capacitor CB, a second capacitor CQB, and a third capacitor C_ON.

In the meantime, a transistor is a three-electrode element including a gate electrode, a source electrode, and a drain electrode. The source electrode is an electrode configured to supply carriers to the transistor. In the transistor, the carriers start flowing from the source electrode. The drain electrode is an electrode through which the carriers are output from the transistor to the outside. Accordingly, the carrier in the MOSFET flows from the source electrode to the drain electrode. In the case of the n-type MOSFET (NMOS), because the carriers are electrons, to allow the electrons to flow from the source electrode to the drain electrode, a voltage of the source electrode is lower than a voltage of the drain electrode. In the n-type MOSFET, because the electrons flow from the source electrode to the drain electrode, the current flows from the drain electrode to the source electrode. In the case of the p-type MOSFET (PMOS), because the carriers are holes, to allow the holes to flow from the source electrode to the drain electrode, a voltage of the source electrode is higher than a voltage of the drain electrode. In the p-type MOSFET, because the holes flow from the source electrode to the drain electrode, the current flows from the source electrode to the drain electrode. However, it should be noted that the source electrode and the drain electrode of the MOSFET are not fixed. For example, the source electrode and the drain electrode of the MOSFET may be changed depending on the applied voltage. In the following example embodiment, the present disclosure should not be limited by the source electrode and the drain electrode of the transistor.

In one example embodiment, stage transistors that configure the gate driver GD may be p-type MOSFET transistors (PMOS transistors) or low temperature polycrystalline silicon (LTPS) thin film transistors. For example, the first to seventh stage transistors M1 to M7 that configure the emission stage included in the emission driver 300 may be PMOS LTPS thin film transistors.

The first stage transistor M1 is connected between a power terminal (hereinafter, referred to as a “second power terminal”) to which the second driving power voltage VEL is supplied and an output terminal from which the i-th emission control signal EMi is output and may include a gate electrode connected to a Q node Q. The first stage transistor M1 may be turned on or turned off based on a voltage of the Q node Q.

For example, the first stage transistor M1 is turned on when a voltage of the Q node Q has a gate-on level (for example, a low level) to electrically connect the second power terminal to which the second driving power voltage VEL is supplied and an output terminal to which the i-th emission control signal EMi is output. For example, in a section in which the first stage transistor M1 is turned on, the i-th emission control signal EMi may have a turn-on level (for example, a low level).

The second stage transistor M2 is connected between a power terminal (hereinafter, “first power terminal”) to which the first driving power voltage VEH is supplied and an output terminal from which the i-th emission control signal EMi is output and may include a gate electrode connected to a QB node QB. The second stage transistor M2 may be turned on or turned off based on a voltage of the QB node QB.

For example, the second stage transistor M2 is turned on when a voltage of the QB node QB has a gate-on level (for example, a low level) to electrically connect the first power terminal to which the first driving power voltage VEH is supplied and an output terminal to which the i-th emission control signal EMi is output. For example, in a section in which the second stage transistor M2 is turned on, the i-th emission control signal EMi may have a turn-off level (for example, a high level).

As described above, the first stage transistor M1 of the emission stage may perform a pull-up function and the second stage transistor M2 may perform a pull-down function.

The third stage transistor M3 is connected between an input terminal (hereinafter, referred to as a “first input terminal”) to which the input signal INP is input and the second control node Q2. The third stage transistor M3 may include a gate electrode that is connected to an input terminal (hereinafter, referred to as a “second input terminal”) to which the emission clock signal ECLK is supplied. The third stage transistor M3 is turned on when the emission clock signal ECLK that is supplied through the second input terminal has a gate-on level (for example, a low level) to electrically connect the first input terminal and the second control node Q2. When the third stage transistor M3 is turned on, the input signal INP that is supplied through the first input terminal may be supplied to the second control node Q2.

The fourth stage transistor M4 is connected between the first power terminal to which the first driving power voltage VEH is supplied and the first control node Q1 and may include a gate electrode connected to the first input terminal to which the input signal INP is input. The fourth stage transistor M4 is turned on when the input signal INP that is supplied through the first input terminal has a gate-on level (for example, a low level) to electrically connect the first power terminal and the first control node Q1. When the fourth stage transistor M4 is turned on, the first driving power voltage VEH with a high level that is supplied through the first power terminal may be supplied to the first control node Q1.

The third capacitor C_ON may be connected between the second input terminal to which the emission clock signal ECLK is supplied and the first control node Q1. For example, the third capacitor C_ON may include a first electrode connected to the second input terminal and a second electrode connected to the first control node Q1.

The third capacitor C_ON may maintain a voltage between the second input terminal and the first control node Q1. Therefore, the third capacitor C-ON may boost the voltage level of the first control node Q1 in response to the voltage level change of the emission clock signal ECLK that is supplied through the second input terminal.

The fifth stage transistor M5 is connected between the second input terminal to which the emission clock signal ECLK is supplied and the QB node QB and may include a gate electrode connected to the first control node Q1. The fifth stage transistor M5 may be turned on or turned off in response to a voltage level of the first control node Q1. When the fifth stage transistor M5 is turned on, the emission clock signal ECLK that is supplied through the second input terminal may be supplied to the QB node QB.

The sixth stage transistor M6 is connected between the first input terminal to which the first driving power voltage VEH is supplied and the QB node QB and may include a gate electrode connected to the second control node Q2. The sixth stage transistor M6 may be turned on or turned off in response to the voltage level of the second control node Q2. When the sixth stage transistor M6 is turned on, the first driving power voltage VEH with a high level that is supplied through the first power terminal may be supplied to the QB node QB.

The seventh stage transistor M7 is connected between the second control node Q2 and the Q node Q and may include a gate electrode connected to the second power terminal to which the second driving power voltage VEL is supplied. Here, the second driving power voltage VEL has a voltage level of a low level so that the seventh stage transistor M7 may always maintain a turn-on state and the second control node Q2 and the Q node Q may maintain an electrically connected state.

The first capacitor CB (or a boosting capacitor) may be connected between the Q node Q and the output terminal. For example, the first capacitor CB may include a first electrode connected to the Q node Q and a second electrode connected to the output terminal.

The second capacitor CQB may be connected between the first power terminal and the QB node QB. For example, the second capacitor CQB may include a first electrode connected to the first power terminal and a second electrode connected to the QB node QB. Here, one electrode (for example, a first electrode) of the second capacitor CQB is connected to the first power terminal to which the first driving power voltage VEH that is a constant power source is supplied so that the second capacitor CQB may charge a voltage applied to the QB node QB and stably maintain a voltage of the QB node QB.

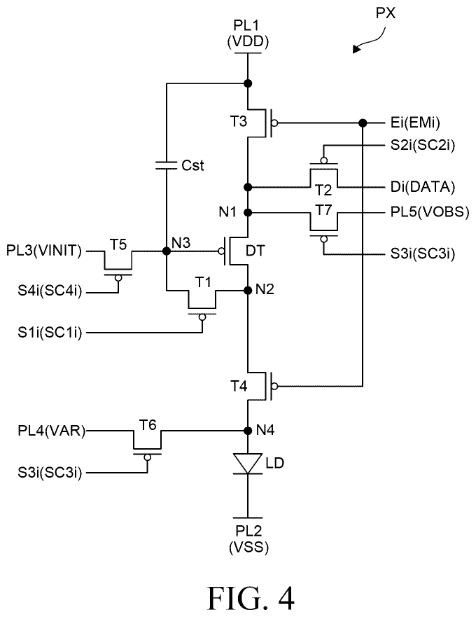

FIG. 4 is a circuit diagram illustrating an example of a pixel included in a display device of FIG. 1.

In FIG. 4, for the convenience of description, a pixel PX that is located in an i-th horizontal line (or an i-th pixel row) and is connected to a j-th data line Dj will be illustrated (where i and j are integers larger than 0). In the meantime, the pixel PX illustrated in FIG. 4 may be substantially the same as the pixel PX that has been described with reference to FIG. 1.

With reference to FIGS. 1 and 4, the pixel PX may include a light emitting diode LD, a driving transistor DT, first to seventh transistors Tl to T7, and a storage capacitor Cst.

A first electrode (for example, an anode electrode) of the light emitting diode LD may be connected to a fourth node N4 (or a second electrode of a fourth transistor T4) and a second electrode (for example, a cathode electrode) may be connected to a second power line PL2 that transmits a second power voltage VSS. The light emitting diode LD may generate light with a predetermined luminance in response to a current amount (a driving current) supplied from the driving transistor DT.

The second power line PL2 may be a line type, but is not limited thereto. For example, the second power line PL2 may be a conductive plate type of conductive layer.

In one example embodiment, the light emitting diode LD may be an organic light emitting diode including an organic emission layer. In another example embodiment, the light emitting diode LD may be an inorganic light emitting diode that is formed with an inorganic material, such as a micro light emitting diode (LED) or a quantum dot light emitting diode. In another example embodiment, the light emitting diode LD may be a light emitting diode in which an organic material and an inorganic material are mixed.

Even though in FIG. 4, it is illustrated that the pixel PX includes a single light emitting diode LD, according to another example embodiment, the pixel PX includes a plurality of light emitting diodes and the plurality of light emitting diodes may be connected to each other in series, parallel, or serial-parallel. For example, in the light emitting diode LD, the plurality of light emitting diodes (for example, organic light emitting diodes and/or inorganic light emitting diodes) may be connected in series, parallel, or serial-parallel, between the second power line PL2 and the fourth node N4.

The first electrode (for example, a source electrode) of the driving transistor DT may be connected to the first node N1 and the second electrode (for example, a drain electrode) may be connected to the second node N2. The gate electrode of the driving transistor DT may be connected to the third node N3. The driving transistor DT may control a driving current (for example, an amount of driving current) that flows from the first power line PL1 configured to supply the first power voltage VDD to the second power line PL2 configured to supply the second power voltage VSS via the light emitting diode LD in response to the voltage of the third node N3, for example, the voltage of the gate electrode. To this end, the first power voltage VDD may be set to be higher than the second power voltage VSS. For example, the first power voltage VDD may be a positive voltage and the second power voltage VSS may be a negative voltage.

The first transistor T1 may be connected between the second electrode (for example, the second node N2) and the gate electrode (for example, the third node N3) of the driving transistor DT. For example, the first electrode (for example, a drain electrode) of the first transistor T1 may be connected to the second node N2 and the second electrode (for example, a source electrode) may be connected to the third node N3. The gate electrode of the first transistor T1 may be connected to the i-th first scan line S1i. When the first scan signal is supplied to the i-th first scan line S1i, the first transistor T1 is turned on to electrically connect the second electrode and the gate electrode of the driving transistor DT (for example, the second node N2 and the third node N3). For example, a timing of connecting the second electrode (e.g., the drain electrode) and the gate electrode of the driving transistor DT may be controlled by the first scan signal. When the first transistor T1 is turned on, the driving transistor DT may be connected in a diode form.

The second transistor T2 may be connected between a j-th data line Dj and the first node N1. For example, the first electrode (e.g., a source electrode) of the second transistor T2 may be connected to the j-th data line Dj and the second electrode (e.g., a drain electrode) may be connected to the first node N1. The gate electrode of the second transistor T2 may be connected to the i-th second scan line S2i. When the second scan signal is supplied to the i-th second scan line S2i, the second transistor T2 is turned on to electrically connect the j-th data line Dj and the first node N1.

The third transistor T3 may be connected between the first power line PL1 and the first node N1. For example, the first electrode (e.g., a source electrode) of the third transistor T3 may be connected to the first power line PL1 and the second electrode (e.g., a drain electrode) may be connected to the first node N1. The gate electrode of the third transistor T3 may be connected to the i-th emission control line Ei. When the emission control signal is supplied to the i-th emission control line Ei, the third transistor T3 may be turned off and otherwise, may be turned on. When the third transistor T3 is turned on, the first node N1 may be electrically connected to the first power line PL1.

The fourth transistor T4 may be connected between the second electrode (for example, a second node N2) of the driving transistor DT and the first electrode (for example, the fourth node N4) of the light emitting diode LD. For example, the first electrode (e.g., a source electrode) of the fourth transistor T4 may be connected to the second node N2 and the second electrode (e.g., a drain electrode) may be connected to the fourth node N4. The gate electrode of the fourth transistor T4 may be connected to the i-th emission control line Ei. The fourth transistor T4 may be controlled in the substantially same manner as the third transistor T3. When the fourth transistor T4 is turned on, the second node N2 and the fourth node N4 may be electrically connected.

In FIG. 4, it is illustrated that the third transistor T3 and the fourth transistor T4 are connected to the same emission control line (for example, i-th emission control line Ei), but it is illustrative and the present disclosure is not limited thereto. For example, the third transistor T3 and the fourth transistor T4 may be connected to separate emission control lines, respectively, to which different emission control signals are supplied.

The fifth transistor T5 may be connected between the third node N3 (for example, the gate electrode of the driving transistor DT) and the third power line PL3 configured to supply the third power voltage VINIT (hereinafter, referred to as “first initialization voltage”). For example, the first electrode (e.g., a drain electrode) of the fifth transistor T5 may be connected to the third power line PL3 and the second electrode (e.g., a source electrode) may be connected to the third node N3. The gate electrode of the fifth transistor T5 may be connected to the i-th fourth scan line S4i. When the fourth scan signal is supplied to the i-th fourth scan line S4i, the fifth transistor T5 is turned on to supply the first initialization voltage VINIT to the third node N3. Here, the first initialization voltage VINIT may be set to be lower than a lowest level of the data signal DATA that is supplied to the j-th data line Dj. The fifth transistor T5 is turned on by supplying the fourth scan signal to initialize a voltage of the gate electrode (or the third node N3) of the driving transistor DT to the first initialization voltage VINIT.

The sixth transistor T6 may be connected between the first electrode (or the fourth node N4) of the light emitting diode LD and the fourth power line PL4 configured to supply the fourth power voltage VAR (hereinafter, referred to as a “second initialization voltage”). For example, the first electrode (for example, a source electrode) of the sixth transistor T6 may be connected to the fourth power line PL4 and the second electrode (for example, a drain electrode) may be connected to the fourth node N4. The gate electrode of the sixth transistor T6 may be connected to the i-th third scan line S3i. When the third scan signal is supplied to the i-th third scan line S3i, the sixth transistor T6 is turned on to supply the second initialization voltage VAR to the fourth node N4 (for example, a first electrode of the light emitting diode LD).

In one example embodiment, when the third scan signal is supplied, the second initialization voltage VAR may be supplied to the first electrode of the light emitting diode LD by the turned-on sixth transistor T6. In this case, the parasitic capacitor of the light emitting diode LD may be discharged. As described above, as a residual voltage charged in the parasitic capacitor of the light emitting diode LD is discharged (removed), unintentional micro-light emission may be suppressed. Accordingly, a black expression ability of the pixel PX may be improved.

In the meantime, a voltage level of the first initialization voltage VINIT and a voltage level of the second initialization voltage VAR may be different from each other. For example, a voltage that initializes the third node N3 and a voltage that initializes the fourth node N4 may be set to be different from each other.

When the first initialization voltage VINIT that is supplied to the third node N3 is significantly low in the low-frequency driving in which a length of one frame period is increased, a strong on-bias is applied to the driving transistor DT so that a threshold voltage of the driving transistor DT in the corresponding frame period may be shifted. Such a hysteresis characteristic may cause a flickering phenomenon in the low frequency driving. Accordingly, in the display device, which is driven at the low frequency, the first initialization voltage VINIT that is higher than the second power voltage VSS may be required.

However, when a voltage level of the second initialization voltage VAR which is supplied to the fourth node N4 to initialize the light emitting diode LD is higher than a predetermined reference, the voltage of the parasitic capacitor of the light emitting diode LD may not be discharged, but may be charged. Accordingly, the voltage level of the second initialization voltage VAR should be sufficiently low to discharge the voltage of the parasitic capacitor of the light emitting diode LD. For example, in consideration of the threshold voltage of the light emitting diode LD, a voltage level of the second initialization voltage VAR may be set to be lower than a sum of the threshold voltage of the light emitting diode LD and the second power voltage VSS.

However, it is illustrative so that the voltage level of the first initialization voltage VINIT and the voltage level of the second initialization voltage VAR may be set in various levels. For example, the voltage level of the first initialization voltage VINIT and the voltage level of the second initialization voltage VAR may be substantially the same.

The seventh transistor T7 may be connected between the first node N1 (or the first electrode of the driving transistor DT) and a fifth power line PL5 configured to supply a fifth power voltage VOBS (hereinafter, referred to as “bias voltage”). For example, the first electrode (for example, a source electrode) of the seventh transistor T7 may be connected to the fifth power line PL5 and the second electrode (for example, a drain electrode) may be connected to the first node N1. The gate electrode of the seventh transistor T7 may be connected to the i-th third scan line S3i.

When the third scan signal is supplied to the i-th third scan line S3i, the seventh transistor T7 is turned on to supply the bias voltage VOBS to the first node N1. In one example embodiment, the bias voltage VOBS may have a level that is similar to a voltage level of a black gray scale data signal DATA. For example, the bias voltage VOBS may have a voltage level of approximately 5 to 7 V, but it is illustrative and the voltage level of the bias voltage VOBS is not limited thereto.

Accordingly, the seventh transistor T7 is turned on to apply a predetermined high voltage to the first electrode (for example, a source electrode) of the driving transistor DT. At this time, when the first transistor T1 is in a turned-on state, the driving transistor DT may be in an on-bias state (a state to be turned on) (e.g., to be on-biased).

Here, as the bias voltage VOBS is periodically supplied to the first node N1, the bias state of the driving transistor DT is periodically changed and a threshold voltage characteristic of the driving transistor DT may be changed. Accordingly, the characteristic of the driving transistor DT may be suppressed from being fixed to a specific state in the low-frequency driving to be degraded.

The storage capacitor Cst may be connected between the first power line PL1 and the third node N3. One electrode of the storage capacitor Cst is connected to the first power line PL1 so that a first power voltage VDD that is a constant voltage may be continuously supplied to one electrode of the storage capacitor Cst. Accordingly, a voltage of the third node N3 may be not affected by other parasitic capacitors and may be maintained to a voltage level of a voltage that is directly supplied to the third node N3. For example, the storage capacitor Cst may store a voltage applied to the third node N3.

In one example embodiment, a pixel PX may include four p-type transistors PMOS including polysilicon semiconductor layers and four n-type transistors NMOS including oxide semiconductor layers.

For example, the driving transistor DT, the second transistor T2, the third transistor T3, and the fourth transistor T4 may be formed by polysilicon semiconductor transistors. For example, the driving transistor DT, the second transistor T2, the third transistor T3, and the fourth transistor T4 may include polysilicon semiconductor layers formed by a low temperature poly-silicon (LTPS) process as active layers (channels). Further, the driving transistor DT, the second transistor T2, the third transistor T3, and the fourth transistor T4 may be polysilicon semiconductor transistors. Therefore, a gate-on voltage that turns on the driving transistor DT, the second transistor T2, the third transistor T3, and the fourth transistor T4 may be a logic low level.

The polysilicon semiconductor transistor has an advantage of fast response speed so that it may be applied to a switching element that requires fast switching.

The first transistor T1, the fifth transistor T5, the sixth transistor T6, and the seventh transistor T7 may be formed by oxide semiconductor transistors. For example, the first transistor T1, the fifth transistor T5, the sixth transistor T6, and the seventh transistor T7 may be N-type oxide semiconductor transistors (e.g., NMOS transistors) and may include oxide semiconductor layers as active layers. Therefore, a gate-on voltage that turns on the first transistor T1, the fifth transistor T5, the sixth transistor T6, and the seventh transistor T7 may be a logic high level.

The oxide semiconductor transistor may be processed at a low temperature and has a lower charge mobility than the polysilicon semiconductor transistor. For example, the oxide semiconductor transistor has an excellent off-current characteristic.

However, the driving transistor DT and the first to seventh transistors T1 to T7 are not limited thereto. Therefore, at least one of the driving transistor DT, the second transistor T2, the third transistor T3, and the fourth transistor T4 may be formed as the oxide semiconductor transistor. Further, at least one of the first transistor T1, the fifth transistor T5, the sixth transistor T6, and the seventh transistor T7 may be formed as a polysilicon semiconductor transistor.

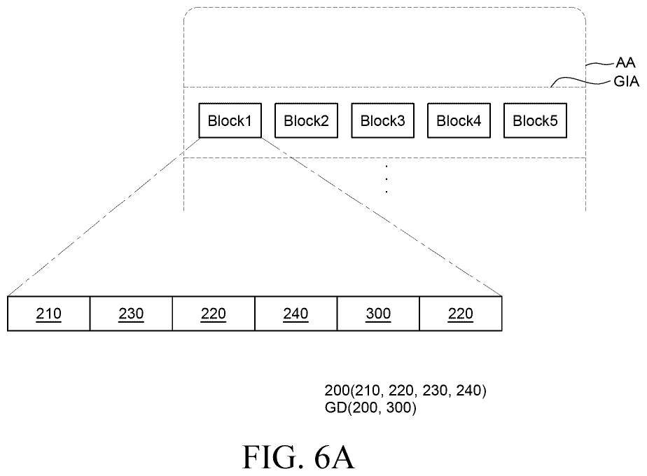

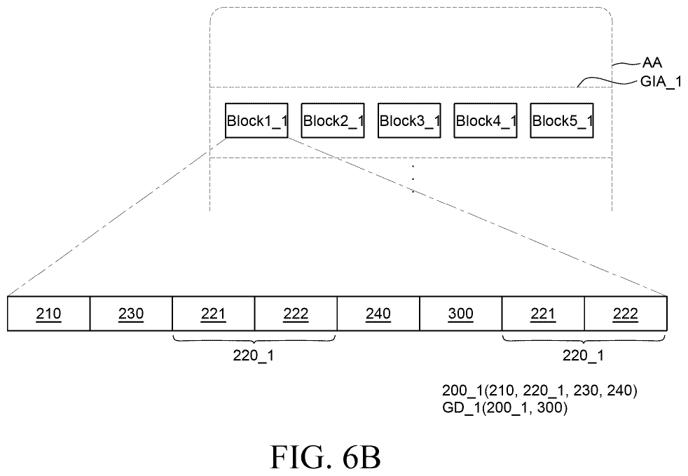

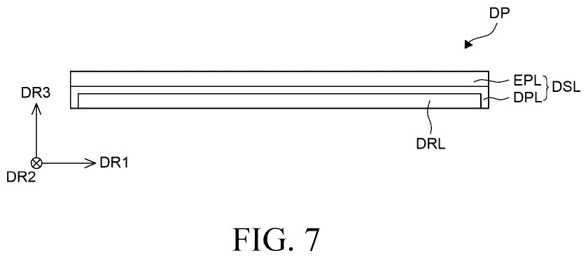

FIG. 5 is a plan view illustrating a display device according to example embodiments of the present disclosure. FIG. 6A is a view for explaining an example of an active area and a gate area included in a display device of FIG. 5. FIG. 6B is a view for explaining another example of an active area and a gate area included in a display device of FIG. 5. FIG. 7 is a cross-sectional view schematically illustrating an example of a display panel included in a display device of FIG. 5.

To avoid redundant description, contents that do not overlap the description with reference to FIGS. 1 to 4 will be mainly described. A part that is not specifically described follows the above-described example embodiment and the same reference numeral denotes the same component and the like reference numeral denotes the like component.

With reference to FIG. 5, a display device 1000 according to the example embodiments of the present disclosure may include a display panel DP, a plurality of pixels PX, a gate driver GD, and a data driver (DD) 400. In one example embodiment, the display device 1000 may further include a printed circuit board PCB and a connection film COF.

The display panel DP may include an active area AA and a non-active area NA that encloses the active area AA. For example, the display panel DP may include a substrate that is divided into an active area AA and a non-active area NA.

The active area AA may be an area where images are displayed. A plurality of pixels PX may be disposed on the active area AA. Each pixel PX may include a display element and various driving elements for driving the display element. For example, various driving elements may include at least one thin film transistor TFT and a capacitor. Further, the pixels PX may be connected to various wiring lines, respectively. For example, each of the pixels PX may be connected to various wiring lines, such as a gate line (e.g., a scan signal line or an emission signal line), a data line, and a power voltage line.

The active area AA may be provided in various shapes. For example, the active area AA of the display device 1000 may be provided to have a rectangular shape having two pairs of parallel sides, but the example embodiments of the present disclosure are not limited thereto.

According to the example embodiment, the active area AA provided in a rectangular shape may have a rounded corner in which one longer side and one shorter side are in contact with each other. However, the example embodiments are not limited thereto so that the active area AA may have a square shape, a polygonal shape, or a circular shape.

In the meantime, for the convenience of description, even though in FIG. 5, it is illustrated that the active area AA has a rectangular shape with rounded corners and a direction parallel to one pair of sides of the active area AA is a first direction DR1 and a direction parallel to the other pair of sides is a second direction DR2. A normal direction of the active area AA, for example, the thickness direction of the display device 1000 may be defined as a third direction DR3.

Front surfaces (or top surfaces) and rear surfaces (or bottom surfaces) of components or units of the display device 1000 to be described below may be distinguished by the third direction DR3. However, the first to third directions DR1, DR2, and DR3 illustrated in the specification are illustrative, and the first to third directions DR1, DR2, and DR3 are relative concepts to be converted into other directions. Hereinafter, for the convenience of description, the same reference numerals refer to the first to third directions DR1, DR2, and DR3.

In the meantime, when it is represented as “overlapping” in the present disclosure, it means that two components overlap in the thickness direction (e.g., the third direction DR3) of the display device 1000, unless otherwise defined.

The non-active area NA may be an area where no image is displayed. The non-active area NA may be disposed to be adjacent to the active area AA. For example, the non-active area NA may be an area that encloses the active area AA. However, it is not limited thereto so that the non-active area NA corresponds to an area excluding the active area AA from the display panel DP and may be modified and/or separated in various forms. Components for driving the pixels PX disposed in the active area AA may be disposed on the non-active area NA. For example, a plurality of pads that is connected to the data driver (DD) 400 may be disposed on the non-active area NA and each pad may be connected to the plurality of pixels PX of the active area AA through data lines that extends from the non-active area NA to the active area AA.

Further, the display panel DP may include a gate area GIA. The gate area GIA may overlap at least a part of the active area AA.

The gate driver GD may be disposed on the gate area GIA. For example, the gate driver GD may be formed on the gate area GIA overlapping at least a part of the active area AA in a gate in array (GIA) manner.

To describe in more detail, with further reference to FIG. 6A, the gate area GIA may overlap at least a part of the active area AA. For example, it may be defined that a part of the active area AA overlaps the gate area GIA.

The gate area GIA may be divided into a plurality of blocks Block1 to Block5. For example, the gate area GIA may be divided into a plurality of blocks Block1 to Block5 that is sequentially disposed along the first direction DR1.

In the meantime, even though in FIG. 6A, it is illustrated that the gate area GIA is divided into five blocks Block1 to Block5, this is illustrative, and the example embodiments of the present disclosure are not limited thereto. For example, the gate area GIA may be divided into four or fewer blocks or six or more blocks.

In each of the blocks Block1 to Block5 of the gate area GIA, the scan driver 200 and the emission driver 300 included in the gate driver GD may be disposed.

For example, in each of the blocks Block1 to Block5 of the gate area GIA, a first scan driver 210, a third scan driver 230, a second scan driver 220, a fourth scan driver 240, an emission driver 300, and a second scan driver 220 may be sequentially disposed along the first direction DR1. Components (for example, transistors, capacitors, and various connection signal lines) included in the first scan driver 210, components (for example, transistors, capacitors, and various connection signal lines) included in the third scan driver 230, components (for example, transistors, capacitors, and various connection signal lines) included in the second scan driver 220, components (for example, transistors, capacitors, and various connection signal lines) included in the fourth scan driver 240, components (for example, transistors, capacitors, and various connection signal lines) included in the emission driver 300, and components (for example, transistors, capacitors, and various connection signal lines) included in the second scan driver 220 may be sequentially disposed along the first direction DR1 in each of the blocks Block1 to Block5 of the gate area GIA.

However, this is illustrative, and the placement order of the drivers is not limited thereto.

In the meantime, as described with reference to FIG. 2B, when the second scan driver 220_1 included in the scan driver 200_1 of the gate driver GD_1 includes two sub scan drivers 221 and 222, in each of the blocks Block1 to Block5 of the gate area GIA_1, the first scan driver 210, the third scan driver 230, a first sub scan driver 221, a second sub scan driver 222, the fourth scan driver 240, the emission driver 300, a first sub scan driver 221, and a second sub scan driver 222 may be sequentially disposed along the first direction DR1.

With reference to FIG. 5 again, in one example embodiment, the display panel DP may include a driving layer DRL on which a gate driver GD and signal lines connected thereto are disposed and a pixel circuit layer DSL on which a pixel PX and signal lines connected thereto are disposed. For example, with further reference to FIG. 7, the display panel DP may include a driving layer DRL and a pixel circuit layer DSL.

On the driving layer DRL, various elements (for example, transistors and capacitors) that configure the gate driver GD and signal lines may be disposed. For example, various elements (e.g., transistors and capacitors) that configure the gate driver GD and the signal lines may be disposed on an area that is defined as the above-described gate area GIA, among the areas of the driving layer DRL. For example, it may be understood that the above-described gate area GIA of the areas of the display panel DP is defined on the driving layer DRL on which the gate driver GD is disposed, but is not limited thereto.

On the pixel circuit layer DSL, various elements (for example, transistors, capacitors, and light emitting diode) that configure the pixel PX and signal lines may be disposed. For example, the pixel circuit layer DSL may include a display element layer DPL on which a display element, such as a transistor and a capacitor, is disposed and a light emitting diode layer EPL that is disposed on the display element layer DPL and includes a light emitting diode. For example, the display element that is included in the display element layer DPL and the light emitting diode included in the light emitting diode layer EPL may be disposed on the active area AA. For example, it is understood that the active area AA (or the active area AA and the non-active area NA) of the above-described area of the display panel DP is defined on the pixel circuit layer DSL on which a display element and a light emitting diode included in the pixel PX are disposed, but it is not limited thereto.

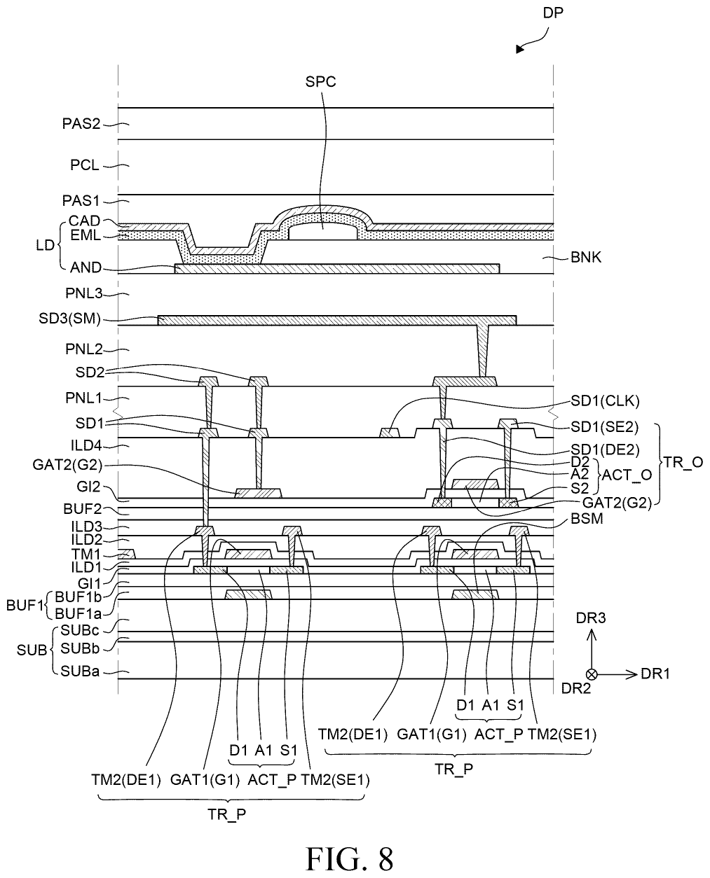

In one example embodiment, the driving layer DRL may be disposed on the same layer as the pixel circuit layer DSL. For example, the driving layer DRL may be disposed on the same layer as the display element layer DPL of the pixel circuit layer DSL. In further to the description above, various elements (for example, transistors and capacitors) that configure the gate driver GD may be disposed on the driving layer DRL and various elements (for example, transistors and capacitors) that configure the pixel PX may be disposed on the display element layer DPL. As described with reference to FIG. 3, the transistors that configure the gate driver GD may be configured by PMOS LTPS thin film transistors. Further, as described with reference to FIG. 4, the transistors that configure the pixel PX may be configured by PMOS LTPS thin film transistors or NMOS oxide thin film transistors. Here, to be described below with reference to FIG. 8, in the transistors that configure the pixel PX, the PMOS LTPS thin film transistors are disposed in a lower portion and the NMOS oxide thin film transistors are disposed in an upper portion. For example, the PMOS LTPS thin film transistors included in the gate driver GD of the driving layer DRL may be disposed on the same layer as a layer on which the PMOS LTPS thin film transistors included in the pixel PX of the pixel circuit layer DSL, for example, the display element layer DPL are disposed. For example, the PMOS LTPS thin film transistors included in the pixel circuit layer DSL, for example, the display element layer DPL and the PMOS LTPS thin film transistors included in the driving layer DRL may be disposed on the same layer.

As described above, in the case of the display device 1000 according to the example embodiments of the present disclosure, the display panel DP includes the driving layer DRL on which various elements configuring the gate driver GD are disposed and the pixel circuit layer DSL on which various elements configuring the pixel PX are disposed. The gate area GIA on which various elements configuring the gate driver GD are disposed may be disposed to overlap at least a part of the active area AA on which various elements configuring the pixel PX are disposed. For example, the transistors (for example, the PMOS LTPS transistors) included in the driving layer DRL may be disposed on the same layer as at least a part (for example, the PMOS LTPS transistors), among transistors included in the pixel circuit layer DSL. For example, the gate driver GD is disposed on the same layer as the pixel circuit layer DSL on which the pixel PX is disposed and is disposed and formed on the gate area GIA that overlaps the active area AA in the gate-in-array manner so that the bezel area of the display device 1000 may be minimized or at least reduced.

Further, as compared with the gate in panel (GIP) manner in which the gate driver is formed at the outside of the active area to supply a gate signal to the pixels, in the display device 1000 according to the example embodiments of the present disclosure, the gate driver GD is disposed in at least a partial area of the active area AA, for example, on the gate area GIA, in the gate in array (GIA) manner. Therefore, the gate signal delay according to the relative position of the pixel PX is minimized or at least reduced to improve the luminance uniformity of the entire active area AA so that the display device 1000 with a high resolution and a large area can be implemented.

With reference to FIG. 5 again, the printed circuit board PCB may transmit signals and voltages for driving the display element from a controller to the display element. Therefore, the printed circuit board PCB may also be referred to as a driving substrate. A controller, such as an IC chip or a circuit unit, may be mounted on the printed circuit board PCB. Further, on the printed circuit board PCB, a memory, a processor, or the like may also be mounted.

The data driver (DD) 400 may supply a data signal to the pixels PX disposed in the active area AA. For example, the data driver (DD) 400 may supply the data signal to the pixels PX through data lines.

In one example embodiment, the data driver (DD) 400 is configured as an integrated circuit chip (IC chip) to be referred to as a data integrated circuit. The data driver (DD) 400 may be mounted in the form of an IC chip on the connection film COF. In the meantime, it is illustrated that in FIG. 5, the data driver (DD) 400 is mounted in the chip on film (COF) manner, but the example embodiments of the present disclosure are not limited thereto. For example, the data driver (DD) 400 may also be mounted in the chip on board (COB), chip on glass (COG), or tape carrier package (TCP) manner.

Hereinafter, a specific cross-sectional structure of a pixel circuit layer DSL included in the display panel DP will be described with reference to FIG. 8. FIG. 8 is a cross-sectional view illustrating an example of a display panel of FIG. 7.

With reference to FIGS. 5, 7, and 8, at least one transistor TR_P and TR_O and a light emitting diode LD may be disposed on the substrate SUB. In the meantime, a first type transistor TR_P, among transistors disposed on the substrate SUB, may be a polysilicon semiconductor transistor. For example, the first type transistor TR_P may be a p-type MOSFET transistor (PMOS transistor) including a polysilicon semiconductor layer formed by a low temperature poly-silicon (LTPS) process as an active layer (channel).

In one example embodiment, as illustrated in FIG. 8, a second type transistor TR_O may be disposed on the first type transistor TR_P. In one example embodiment, the first type transistor TR_P may be at least one of the driving transistor DT, the second transistor T2, the third transistor T3, and the fourth transistor T4 included in the pixel PX that have been described with reference to FIG. 4.

Further, in one example embodiment, the transistors (for example, the PMOS LTPS transistors) of the gate driver GD is disposed on the same layer as the PMOS LTPS transistors, among transistors that configure the pixel PX. Therefore, the first type transistor TR_P may be at least one of the first to seventh stage transistors M1 to M7 included in the gate driver GD that have been described with reference to FIG. 3.

Further, the second type transistor TR_O, among transistors disposed on the substrate SUB, may be an oxide semiconductor transistor. For example, the second type transistor TR_O may be an n-type MOSFET transistor (NMOS transistor) including an oxide semiconductor layer as an active layer (channel). For example, the second type transistor TR_O may be at least one of the first transistor T1, the fifth transistor T5, the sixth transistor T6, and the seventh transistor T7 included in the pixel PX that have been described with reference to FIG. 4.

The substrate SUB is a base member of the pixel circuit layer DSL and may be substantially a transparent and transmissive substrate. The substrate SUB may be a flexible substrate formed of a plastic material. Here, the flexible property may be interpreted as the same meaning as bendable, unbreakable, rollable, and foldable properties.

For example, the substrate SUB may include plastic, and in this case, the substrate SUB may be referred to as a plastic film or a plastic substrate. For example, the substrate SUB may include at least one selected from a group consisting of a polyester-based polymer, a silicon-based polymer, an acrylic polymer, a polyolefin-based polymer, and a polymer thereof. For example, the substrate SUB may include polyimide (PI).

In the meantime, when the substrate SUB includes polyimide (PI), moisture passes through the substrate SUB formed of polyimide (PI) and permeates the thin film transistor, etc. included in the pixel PX so that the reliability of the pixel PX is lowered and thus a performance of the display device 1000 may be degraded.

Accordingly, in one example embodiment, the substrate SUB may include double polyimide (PI). Further, the substrate SUB further includes an inorganic film formed between two polyimides (PI) to block the moisture components from permeating the lower polyimide (PI), so that the reliability of the product performance may be further improved. Further, an inorganic film is formed between two polyimides (PI) to block charges charged in the lower polyimide (PI), thereby further improving the reliability of the product.

For example, as illustrated in FIG. 8, the substrate SUB may include a first sub substrate SUBa including polyimide (PI), a second substrate SUBb that is disposed on the first sub substrate SUBa and includes an inorganic insulating material, and a third sub substrate SUBc that is disposed on the second sub substrate SUBb and includes polyimide PI.

The inorganic insulating material included in the second sub substrate SUBb may be formed by a single layer of silicon nitride (SiNx) or silicon oxide (SiOx) or a multilayer thereof. However, this is illustrative, and example embodiments of the present disclosure are not limited thereto. For example, the inorganic insulating material included in the second sub substrate SUBb may include a silicon oxide (SiOx) material. For example, the inorganic insulating material included in the second sub substrate SUBb may include silicon dioxide (silica, SiO₂). As another example, the inorganic insulating material included in the second sub substrate SUBb may be formed by a double layer of silicon dioxide (SiO₂) and silicon nitride (SiNx).

In the meantime, even though it is not separately illustrated in FIG. 8, a back plate and a metal plate may be further disposed below the substrate SUB.

A shielding metal layer including at least one shielding metal pattern BSM may be disposed on the substrate SUB. The shielding metal pattern BSM included in the shielding metal layer may be formed by a single layer or a multilayer formed of any one of molybdenum (Mo), copper (Cu), titanium (Ti), aluminum (Al), chrome (Cr), gold (Au), nickel (Ni), and neodymium (Nd) or an alloy thereof.

According to an example embodiment, the shielding metal pattern BSM may be defined as a component included in the first type transistor TR_P. For example, the shielding metal pattern BSM may configure a lower gate electrode of the first type transistor TR_P.

The first buffer layer BUF1 may be disposed on the substrate SUB. For example, the first buffer layer BUF1 may be disposed on the substrate SUB to cover the shielding metal pattern BSM.

In one example embodiment, the first buffer layer BUF1 may include a multi-buffer layer BUF1a disposed on the substrate SUB and an active buffer layer BUF1b disposed on the multi-buffer layer BUF1a.

The first type transistor TR_P may be disposed on the first buffer layer BUF1. The first type transistor TR_P may include a first semiconductor pattern ACT_P, a first gate electrode G1, a source electrode SE1, and a drain electrode DE1. According to the example embodiment, as described above, the first type transistor TR_P may further include the shielding metal pattern BSM disposed between the first buffer layer BUF1 and the substrate SUB. A first semiconductor layer including at least one first semiconductor pattern ACT_P may be disposed on the first buffer layer BUF1.

For example, the first semiconductor pattern ACT_P of the first semiconductor layer included in the first type transistor TR_P may be disposed on the first buffer layer BUF1. The first semiconductor pattern ACT_P may include a first area S1 (or a source electrode or a source region), a second area D1 (or a drain electrode or a drain region), and a channel area A1 therebetween. Further, as described above, the first semiconductor pattern ACT_P may include a polysilicon semiconductor layer formed by a low temperature poly-silicon (LTPS) process.

For example, a first gate insulating layer GI1 may be disposed on the first semiconductor layer, for example, the first semiconductor pattern ACT_P. For example, the first gate insulating layer GI1 is disposed to cover the first semiconductor layer, for example, the first semiconductor pattern ACT_P to insulate the first semiconductor pattern ACT_P of the first type transistor TR_P from the first gate electrode G1.

For example, the first gate insulating layer GI1 may be configured by a single layer of silicon nitride (SiNx) or silicon oxide (SiOx) or a multilayer thereof, but is not limited thereto.

A first conductive layer GAT1 may be disposed on the first gate insulating layer GI1. The first conductive layer GAT1 may configure at least a part of the emission control line Ei, the third power line PL3 configured to supply the first initialization voltage VINIT or the second scan line S2i. Here, the first conductive layer GAT1 configures at least a part of the third power line PL3 configured to supply the first initialization voltage VINIT so that the first conductive layer GAT1 may include a material having a high conductivity, such as a metal or conductive oxide. For example, the first conductive layer GAT1 may be formed by a single layer or a multilayer including aluminum (Al), copper (Cu), or titanium (Ti). In some example embodiments, the first conductive layer GAT1 may be provided as a triple layer of titanium, aluminum, and titanium (Ti/Al/Ti) that are sequentially disposed.

A first gate electrode G1 of the first type transistor TR_P that configures at least a part of the emission control line (for example, Ei) or the scan line (for example, S2i) of the first conductive layer GAT1 may be disposed on the first gate insulating layer GI1.

The first gate electrode G1 of the first type transistor TR_P may be disposed to at least partially overlap the first semiconductor pattern ACT_P.

A first insulating layer ILD1 may be disposed on the first conductive layer GAT1, for example, the first gate electrode G1 of the first type transistor TR_P. For example, the first insulating layer ILD1 may be disposed to cover the first conductive layer GAT1, for example, the first gate electrode G1 of the first type transistor TR_P. The first insulating layer ILD1 may be configured by a single layer of silicon nitride (SiNx) or silicon oxide (SiOx) or a multilayer thereof, but is not limited thereto.

A second conductive layer TM1 may be disposed on the first insulating layer ILD1. The second conductive layer TM1 includes molybdenum (Mo), copper (Cu), and titanium (Ti), and may be formed by a single layer or a multilayer.

A second insulating layer ILD2 may be disposed on the second conductive layer TM1. For example, the second insulating layer ILD2 may be disposed to cover the second conductive layer TM1.

The first insulating layer ILD1 may be configured by a single layer of silicon nitride (SiNx) or silicon oxide (SiOx) or a multilayer thereof, but is not limited thereto.

A third conductive layer TM2 may be disposed on the second insulating layer ILD2. The third conductive layer TM2 includes molybdenum (Mo), copper (Cu), and titanium (Ti), and may be formed by a single layer or a multilayer.

For example, a first source electrode SE1 and a first drain electrode DE1 of the first type transistor TR_P of the third conductive layer TM2 may be disposed on the second insulating layer ILD2. The first source electrode SE1 of the first type transistor TR_P of the third conductive layer TM2 may be in contact with a first area S1 of the first semiconductor pattern ACT_P through a contact hole that passes through the second insulating layer ILD2, the first insulating layer ILD1, and the first gate insulating layer GI1. The first drain electrode DE1 of the first type transistor TR_P of the third conductive layer TM2 may be in contact with a second area D1 of the first semiconductor pattern ACT_P through the contact hole that passes through the second insulating layer ILD2, the first insulating layer ILD1, and the first gate insulating layer GI1.

A third insulating layer ILD3 may be disposed on the third conductive layer TM2, for example, the first source electrode SE1 and the first drain electrode DE1 of the first type transistor TR_P. For example, the third insulating layer ILD3 may be disposed to cover the third conductive layer TM2.

The third insulating layer ILD3 may be configured by a single layer of silicon nitride (SiNx) or silicon oxide (SiOx) or a multilayer thereof, but is not limited thereto.

A second buffer layer BUF2 may be disposed on the third insulating layer ILD3.

The second buffer layer BUF2 may be configured by a single layer of silicon nitride (SiNx) or silicon oxide (SiOx) or a multi-layer thereof, but is not limited thereto.

A second semiconductor layer including at least one second semiconductor pattern ACT_O may be disposed on the second buffer layer BUF2.

For example, the second semiconductor pattern ACT_O of the second semiconductor layer included in the second type transistor TR_O may be disposed on the second buffer layer BUF2. The second semiconductor pattern ACT_O may include a first area S2 (or a source electrode or a source region), a second area D2 (or a drain electrode or a drain region), and a channel area A2 therebetween. Further, as described above, the second semiconductor pattern ACT_O may include an oxide semiconductor layer.

A second gate insulating layer GI2 may be disposed on the second semiconductor layer, for example, the second semiconductor pattern ACT_O. The second gate insulating layer GI2 may be configured by a single layer of silicon nitride (SiNx) or silicon oxide (SiOx) or a multilayer thereof, but is not limited thereto.

A fourth conductive layer GAT2 may be disposed on the second gate insulating layer GI2. The fourth conductive layer GAT2 includes molybdenum (Mo), copper (Cu), and titanium (Ti), and may be formed by a single layer or a multilayer.

For example, the second gate electrode G2 of the second type transistor TR_O that configures at least some of the scan lines (for example, S1i, S3i, and S4i) of the fourth conductive layer GAT2 may be disposed on the second gate insulating layer GI2.

The second gate electrode G2 of the second type transistor TR_O may be disposed to at least partially overlap the second semiconductor pattern ACT_O.

A fourth insulating layer ILD4 may be disposed on the fourth conductive layer GAT2, for example, the second gate electrode G2 of the second type transistor TR_O. For example, the fourth insulating layer ILD4 may be disposed to cover the fourth conductive layer GAT2, for example, the second gate electrode G2 of the second type transistor TR_O.

A fifth conductive layer SD1 may be disposed on the fourth insulating layer ILD4. The fifth conductive layer SD1 may configure at least a part of the fourth power line PLA configured to supply the second initialization voltage VAR or the fifth power line PL5 configured to supply the bias voltage VOBS, described with reference to FIG. 4. Here, the fifth conductive layer SD1 configures at least a part of the fourth power line PL4 configured to supply the second initialization voltage VAR or the fifth power line PL5 configured to supply the bias voltage VOBS so that the fifth conductive layer SD1 may include a material having a high conductivity, such as a metal or conductive oxide. For example, the fifth conductive layer SD1 may be formed by a single layer or a multilayer including aluminum (Al), copper (Cu), or titanium (Ti). In some example embodiments, the fifth conductive layer SD1 may be provided as a triple layer of titanium, aluminum, and titanium (Ti/Al/Ti) that are sequentially disposed.

Further, at least a part of the fifth conductive layer SD1 may serve as a connection electrode. For example, at least a part of the fifth conductive layer SD1 is connected to the source electrode SE1 and/or the drain electrode DE1 of the first type transistor TR_P of the third conductive layer TM2 through a contact hole that passes through the fourth insulating layer ILD2, the second gate insulating layer GI2, the second buffer layer BUF2, and the third insulating layer ILD3. Alternatively, at least a part of the fifth conductive layer SD1 may be in contact with a part of the fourth conductive layer GAT2 through a contact hole that passes through the fourth insulating layer ILD4.

Further, at least a part of the fifth conductive layer SD1 may configure the second source electrode SE2 and the second drain electrode DE2 of the second type transistor TR_O. For example, the second source electrode SE2 of the second type transistor TR_O of the fifth conductive layer SD1 may be in contact with a first area S2 of the second semiconductor pattern ACT_O through a contact hole that passes through the fourth insulating layer ILD4 and the second gate insulating layer GI2. The second drain electrode DE2 of the second type transistor TR_O of the fifth conductive layer SD1 may be in contact with a second area D2 of the second semiconductor pattern ACT_O through the contact hole that passes through the fourth insulating layer ILD4 and the second gate insulating layer GI2.

In one example embodiment, at least a part of the fifth conductive layer SD1 may configure a clock line CLK that is connected to the driving layer DRL of the display panel DP that has been described with reference to FIGS. 5 to 7. For example, at least a part of the fifth conductive layer SD1 may configure a clock line CLK that transmits a clock signal that is an input signal of each stage included in the gate driver GD (for example, the scan driver 200 and/or the emission driver 300). For example, the clock line CLK of the fifth conductive layer SD1 that transmits a clock signal may be electrically connected to each stage (for example, at least a part of a transistor that configures each stage) of the gate driver GD disposed on the driving layer DRL by means of a line jumping structure. For example, as described above, at least some of the first type transistors TR_P configure at least some of the stage transistors M1 to M7 of the gate driver GD so that at least a part of the fifth conductive layer SD1 that configures the clock line CLK may be electrically connected to any one of the first type transistors TR_P.

A first planarization layer PNL1 may be disposed on the fifth conductive layer SD1. The first planarization layer PNL1 may be an organic layer that planarizes an upper portion and protects components disposed therebelow. For example, the first planarization layer PNL1 may include an organic material, such as acryl resin, epoxy resin, phenolic resin, polyamide resin, or polyimide resin.

A sixth conductive layer SD2 may be disposed on the first planarization layer PNL1.

The sixth conductive layer SD2 may configure at least a part of the data line Dj or the first power line PL1 configured to supply the first power voltage VDD, described with reference to FIG. 4. Here, the sixth conductive layer SD2 configures at least a part of the first power line PL1 configured to supply the first power voltage VDD so that the sixth conductive layer SD2 may include a material having a high conductivity, such as a metal or conductive oxide. For example, the sixth conductive layer SD2 may be formed by a single layer or a multilayer including aluminum (Al), copper (Cu), or titanium (Ti). In some example embodiments, the sixth conductive layer SD2 may be provided as a triple layer of titanium, aluminum, and titanium (Ti/Al/Ti) that are sequentially disposed.

Further, at least a part of the sixth conductive layer SD2 may serve as a connection electrode. For example, at least a part of the sixth conductive layer SD2 may be connected to at least a part of the fifth conductive layer SD1 through a contact hole that passes through the first planarization layer PNL1.

A second planarization layer PNL2 may be disposed on the sixth conductive layer SD2. The second planarization layer PNL2 may be an organic layer that planarizes an upper portion and protects components disposed therebelow. For example, the second planarization layer PNL2 may include an organic material, such as acryl resin, epoxy resin, phenolic resin, polyamide resin, or polyimide resin.

A seventh conductive layer SD3 may be disposed on the second planarization layer PNL2. The seventh conductive layer SD3 may be formed of a single layer or a multilayer formed of any one of molybdenum (Mo), copper (Cu), titanium (Ti), aluminum (Al), chrome (Cr), gold (Au), nickel (Ni), and neodymium (Nd) or an alloy thereof.

In one example embodiment, at least a part of the seventh conductive layer SD3 may serve as a shielding pattern SM. For example, as described above, at least a part of the fifth conductive layer SD1 configures at least a part of a clock line CLK that transmits a clock signal to the gate driver GD of the driving layer DRL. Therefore, there may be a signal interference between the clock line CLK of the fifth conductive layer SD1 and the anode electrode AND of the light emitting diode LD of the light emitting diode layer EPL disposed above the display element layer DPL. In this case, the voltage of the anode electrode AND of the light emitting diode LD (for example, a voltage of the fourth node N4 described with reference to FIG. 4) is unstable so that a display quality of the desired pixel PX may be degraded. Therefore, in the case of the display device 1000 according to the example embodiments of the present disclosure, the seventh conductive layer SD3 disposed above the second planarization layer PNL2 serves as a shielding pattern SM that shields a signal between at least a part (for example, a clock line CLK) of the fifth conductive layer SD1 and the anode electrode AND of the light emitting diode LD of the light emitting diode layer EPL. Therefore, the display quality may be improved.

According to the example embodiment, for the shielding function, the shielding pattern SM of the seventh conductive layer SD3 may have a width larger than a width of the anode electrode AND of the light emitting diode LD. Further, at least a part of the seventh conductive layer SD3 may be connected to at least a part of the sixth conductive layer SD2 through a contact hole that passes through the second planarization layer PNL2.

A third planarization layer PNL3 may be disposed on the seventh conductive layer SD3. The third planarization layer PNL3 may be an organic layer that planarizes an upper portion and protects components disposed therebelow. For example, the third planarization layer PNL3 may include an organic material, such as acryl resin, epoxy resin, phenolic resin, polyamide resin, or polyimide resin.

The light emitting diode LD may be disposed on the third planarization layer PNL3. The light emitting diode LD may include an anode electrode AND (or a first electrode), a cathode electrode CAD (or a second electrode), and an emission layer EML formed therebetween. The anode electrode AND may be disposed on the third planarization layer PNL3.

In the meantime, when the display device 1000 is a top emission type in which light emitted from the light emitting diode LD is emitted above the substrate SUB in which the light emitting diode LD is disposed, the anode electrode AND may further include a transparent conductive layer and a reflective layer on the transparent conductive layer. The transparent conductive layer may be formed of transparent conductive oxide such as ITO or IZO and for example, the reflective layer may include silver (Ag), aluminum (Al), gold (Au), molybdenum (Mo), tungsten (W), chrome (Cr), or an alloy thereof.

A bank layer BNK is disposed to cover at least a part of the anode electrode AND and may open the remaining part of the anode electrode AND. For example, the bank layer BNK may be disposed to open a part corresponding to an emission area of the pixel PX. Therefore, a part of the anode electrode AND may be exposed by the open part of the bank layer BNK. The bank layer BNK may include an inorganic insulating material, such as silicon nitride (SiNx) or silicon oxide (SiOx), or an organic insulating material, such as benzocyclobutene resin, acrylic resin or imide resin, but is not limited thereto.

The emission layer EML may be disposed on the entire surface of the pixel PX on top surfaces of the bank layer BNK and the anode electrode AND. In the meantime, a part of the emission layer EML may be in contact with the exposed part of the anode electrode AND by the open part of the bank layer BNK. According to the example embodiment, the emission layer EML may include a plurality of organic films.

The cathode electrode CAD may be disposed on the emission layer EML. For example, the cathode electrode CAD may be disposed on the front surface of the pixel PX. The light emitting diode LD may be formed by the anode electrode AND, the emission layer EML, and the cathode electrode CAD.

In the meantime, a spacer SPC may be provided so as not to cause a screen mask and the substrate to be in contact with each other during a process of depositing the emission layer EML. The spacer SPC is disposed on the bank layer BNK and the emission layer EML and the cathode electrode CAD may be applied to pass over the spacer SPC disposed in the active area AA.

According to the example embodiment, the emission layer EML and/or the cathode electrode CAD may not pass over the spacer SPC. The spacer SPC is disposed only in a part of the bank layer BNK in the active area AA so that even though the cathode electrode CAD does not pass over the spacer SPC, the cathode electrode CAD may be connected while covering the overall active area AA.

An encapsulation layer may be disposed above the light emitting diode LD. For example, the encapsulation layer may include a first inorganic encapsulation layer PAS1, an organic encapsulation layer PCL on the first inorganic encapsulation layer PAS1, and a second inorganic encapsulation layer PAS2 on the organic encapsulation layer PCL. The first inorganic encapsulation layer PAS1 and the second inorganic encapsulation layer PAS2 may serve to block the permeation of moisture or oxygen. For example, the first inorganic encapsulation layer PAS1 and the second inorganic encapsulation layer PAS2 may be formed of an inorganic material such as silicon nitride, aluminum nitride, zirconium nitride, titanium nitride, hafnium nitride, tantalum nitride, silicon oxide, aluminum oxide, or titanium nitride. The first inorganic encapsulation layer PAS1 and the second inorganic encapsulation layer PAS2 may be formed by a chemical vapor deposition process or an atomic layer deposition process.

The organic encapsulation layer PCL may be disposed between the first inorganic encapsulation layer PAS1 and the second inorganic encapsulation layer PAS2. The organic encapsulation layer PCL may be formed with a thickness larger than that of the first inorganic encapsulation layer PAS1 and/or the second inorganic encapsulation layer PAS2 to suck and/or block particles that may be generated during the manufacturing process. The organic encapsulation layer PCL may be formed of an organic material such as silicon oxy carbon SiOCz acryl or epoxy resin. The organic encapsulation layer PCL may be formed by a coating process, such as an inkjet coating process or a slit coating process.

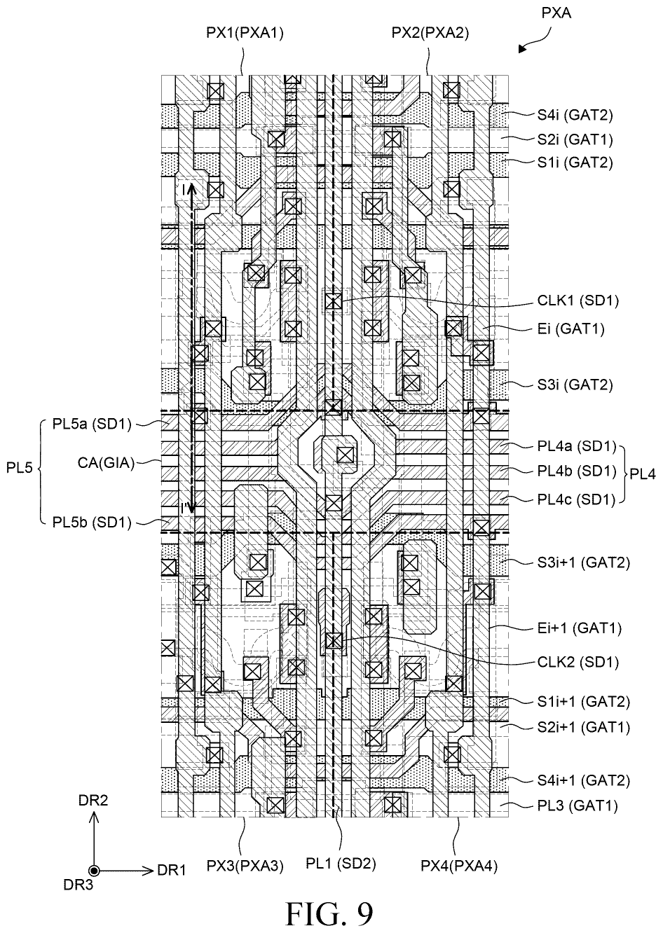

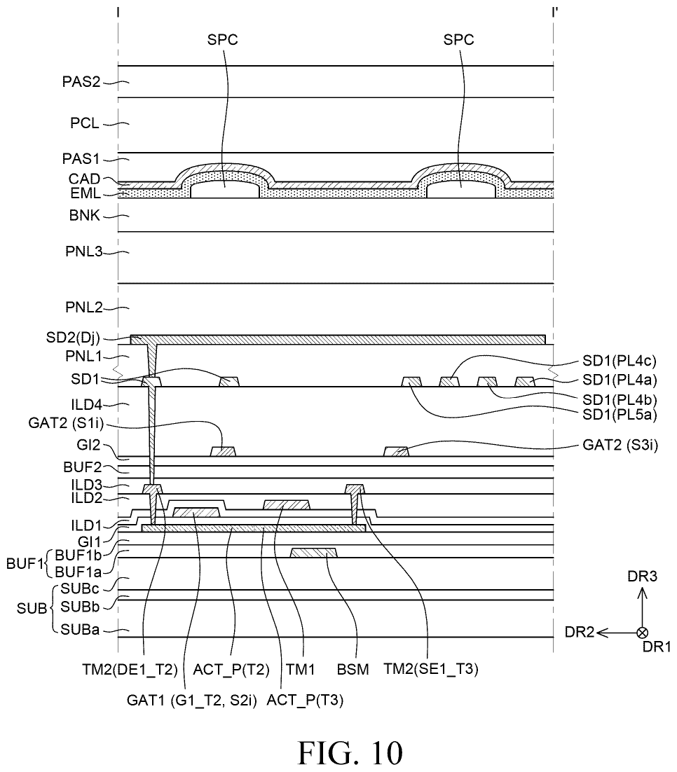

FIG. 9 is a layout illustrating an example of a pixel included in a display device of FIG. 5. FIG. 10 is a cross-sectional view illustrating an example taken along the line I-I′ of FIG. 9.

To avoid redundant descriptions, contents that do not overlap the description with reference to FIGS. 1 to 8 will be mainly described. A part that is not specifically described follows the above-described example embodiment and the same reference numeral denotes the same component and the like reference numeral denotes the like component.

In the meantime, in FIG. 9, a first pixel PX1, a second pixel PX2, a third pixel PX3, and a fourth pixel PX4 that are substantially the same as the pixel PX described with reference to FIG. 4 and disposed in a first pixel area PXA1, a second pixel area PXA2, a third pixel area PXA3, and a fourth pixel area PXA4, respectively, are illustrated.

In the meantime, the pixels PX1 to PX4 illustrated in FIG. 9 may substantially be the same as the pixel PX disposed on the display panel DP (for example, a pixel circuit layer DSL) of the display device 1000 that has been described with reference to FIGS. 1 to 8. With reference to FIGS. 1 to 9, the display panel DP, for example, the pixel circuit layer DSL may include a pixel area PXA in which the pixel PX is disposed. For example, as illustrated in FIG. 9, the pixel area PXA may include a first pixel area PXA1, a second pixel area PXA2, a third pixel area PXA3, and a fourth pixel area PXA4. The first pixel PX1 is provided in the first pixel area PXA1, the second pixel PX2 is provided in the second pixel area PXA2, the third pixel PX3 is provided in the third pixel area PXA3, and the fourth pixel PX4 is provided in the fourth pixel area PXA4.

In one example embodiment, the pixel PX (or the pixel area PXA) may have a vertical flip structure. For example, the first pixel area PXA1 and the second pixel area PXA2 are disposed to be adjacent to each other along the first direction DR1 and may be symmetric to each other with respect to the first power line PL1 extending along the second direction DR2.

Further, the third pixel area PXA3 and the fourth pixel area PXA4 are disposed to be adjacent to each other along the first direction DR1 and may be symmetric to each other with respect to the first power line PL1 extending along the second direction DR2. Further, the first pixel area PXA1 and the third pixel area PXA3 are disposed to be adjacent to each other along the second direction DR2 and may be symmetric to each other with respect to the fourth power line PLA and/or the fifth power line PL5 extending along the first direction DR1. Further, the second pixel area PXA2 and the fourth pixel area PXA4 are disposed to be adjacent to each other along the second direction DR2 and may be symmetric to each other with respect to the fourth power line PLA and/or the fifth power line PL5 extending along the first direction DR1.

Accordingly, the first pixel PX1, the second pixel PX2, the third pixel PX3, and the fourth pixel PX4 may include a substantially similar or the same configuration. Accordingly, hereinafter, one pixel PX that is disposed in one pixel area PXA will be described with respect to the first pixel PX1 disposed in the first pixel area PXA1. For the second pixel PX2, the third pixel PX3, and the fourth pixel PX4 disposed in the second pixel area PXA2, the third pixel area PXA3, and the fourth pixel area PXA4, respectively, a redundant description will not be repeated.

In one example embodiment, the pixel area PXA may include a center area CA disposed between the first pixel area PXA1 and the second pixel area PXA2, and the third pixel area PXA3 and the fourth pixel area PXA4. Here, the center area CA may be an area that overlaps the gate area GIA that has been described with reference to FIGS. 5 to 7. For example, in the center area CA of the pixel area PXA of the pixel circuit layer DSL, the gate driver GD disposed on the gate area GIA of the driving layer DRL may be disposed. In other words, a transistor, a capacitor, and a signal line that configure the gate driver GD may be disposed on the center area CA of the pixel area PXA of the pixel circuit layer DSL.

According to the example embodiment, the center area CA extends along the first direction DR1 to be disposed on the entire active area AA. For example, the center area CA may be defined in response to the gate area GIA that has been described with reference to FIG. 5. Further, according to the example embodiment, a width of the center area CA along the second direction DR2 may be smaller than a width of each pixel area PXA1, PXA2, PXA3, or PXA4 along the second direction DR2. However, this is illustrative, and the example embodiments of the present disclosure are not limited thereto.

With further reference to FIG. 10, the substrate SUB and the first buffer layer BUF1 may be sequentially disposed on the pixel area PXA. According to the example embodiment, a shielding metal layer including a shielding metal pattern BSM may be disposed between the substrate SUB and the first buffer layer BUF1.

A first semiconductor layer including at least one first semiconductor pattern ACT_P may be disposed on the first buffer layer BUF1. For example, as illustrated in FIG. 10, a first semiconductor pattern ACT_P of the second transistor T2 and a first semiconductor pattern ACT_P of the third transistor T3 may be disposed.

The first gate insulating layer GI1 may be disposed on the first semiconductor layer and the first conductive layer GAT1 may be disposed on the first gate insulating layer GI1. For example, as illustrated in FIG. 10, the gate electrode G1_T2 of the second transistor T2 that configures at least a part of the second scan line S2i of the first conductive layer GAT1 may be disposed on the first gate insulating layer GI1.

Further, as illustrated in FIG. 9, the first conductive layer GAT1 extends along the first direction DR1 with respect to the first pixel area PXA1 and the second pixel area PXA2 and may include the third power line PL3, the second scan line S2i, and the emission control line Ei that are sequentially disposed along the second direction DR2.

In the meantime, as described above, the pixel PX (or the pixel area PXA) has a vertical flip structure (for example, the first pixel area PXA1 and the third pixel area PXA3 are symmetric to each other and the second pixel area PXA2 and the fourth pixel area PXS4 are symmetric to each other). With respect to the third pixel area PXA3 and the fourth pixel area PXA4, an emission control line Ei+1, a second scan line S2i+1, and a third power line PL3 included in the first conductive layer GAT1 extend along the first direction DR1. The emission control line Ei+1, the second scan line S2i+1, and the third power line PL3 may be sequentially disposed along the second direction DR2 in this order.

For example, a placement order of the third power line PL3, the second scan line S2i, and the emission control line Ei included in the first conductive layer GAT1 along the second direction DR2 in the first pixel area PXA1 and the second pixel area PXA2 and a placement order of the emission control line Ei+1, the second scan line S2i+1, and the third power line PL3 included in the first conductive layer GAT1 along the second direction DR2 in the third pixel area PXA3 and the fourth pixel area PXA4 may be opposite to each other.

The first insulating layer ILD1, the second conductive layer TM1, and the second insulating layer ILD2 may be sequentially disposed on the first conductive layer GAT1.

The third conductive layer TM2 may be disposed on the second insulating layer ILD2. For example, as illustrated in FIG. 10, a part of the third conductive layer TM2 may configure a drain electrode DE1_T2 of the second transistor T2 and the other part may configure a source electrode SE1_T3 of the third transistor T3.

The third insulating layer ILD3, the second buffer layer BUF2, the second semiconductor layer, and the second gate insulating layer GI2 may be sequentially disposed on the third conductive layer TM2.

The fourth conductive layer GAT2 may be disposed on the second gate insulating layer GI2. For example, as illustrated in FIG. 10, at least a part of the fourth conductive layer GAT2 may configure the first scan line S1i and at least the other part of the fourth conductive layer GAT2 may configure the third scan line S3i.

Further, as illustrated in FIG. 9, the fourth conductive layer GAT2 extends along the first direction DR1 with respect to the first pixel area PXA1 and the second pixel area PXA2 and may include the fourth scan line S4i, the first scan line S1i, and the third scan line S3i that are sequentially disposed along the second direction DR2.

In the meantime, as described above, the pixel PX (or the pixel area PXA) has a vertical flip structure (for example, the first pixel area PXA1 and the third pixel area PXA3 are symmetric to each other and the second pixel area PXA2 and the fourth pixel area PXS4 are symmetric to each other). With respect to the third pixel area PXA3 and the fourth pixel area PXA4, the third scan line S3i+1, the first scan line S1i+1, and the fourth scan line S4i+1 included in the fourth conductive layer GAT2 extend along the first direction DR1. The third scan line S3i+1, the first scan line S1i+1, and the fourth scan line S4i+1 may be sequentially disposed along the second direction DR2 in this order.

For example, a placement order of the fourth scan line S4i+1, the first scan line S1i, and the third scan line S3i included in the fourth conductive layer GAT2 along the second direction DR2 in the first pixel area PXA1 and the second pixel area PXA2 and a placement order of the third scan line S3i+1, the first scan line S1i+1, and the fourth scan line S4i+1 included in the fourth conductive layer GAT2 along the second direction DR2 in the third pixel area PXA3 and the fourth pixel area PXA4 may be opposite to each other.

According to the example embodiments, as illustrated in FIG. 9, the first conductive layer GAT1 and the second conductive layer GAT2 may include different kinds of metal materials. For example, the first conductive layer GAT1 and the second conductive layer GAT2 may include different metal materials.

Here, the third power line PL3, the second scan line S2i, and the emission control line Ei included in the first conductive layer GAT1 and the fourth scan line S4i, the first scan line S1i, and the third scan line S3i included in the fourth conductive layer GAT2 may be alternately disposed along the second direction DR2. For example, the third power line PL3 of the first conductive layer GAT1, the fourth scan line S4i of the fourth conductive layer GAT2, the second scan line S2i of the first conductive layer GAT1, the first scan line S1i of the fourth conductive layer GAT2, the emission control line Ei of the first conductive layer GAT1, and the third scan line S3i of the fourth conductive layer GAT2 may be sequentially disposed with respect to the first pixel area PXA1 and the second pixel area PXA2. As another example, the third scan line S3i of the fourth conductive layer GAT2, the emission control line Ei of the first conductive layer GAT1, the first scan line S1i of the fourth conductive layer GAT2, the second scan line S2i of the first conductive layer GAT1, the fourth scan line S4i of the fourth conductive layer GAT2, and the third power line PL3 of the first conductive layer GAT1 may be sequentially disposed with respect to the third pixel area PXA3 and the fourth pixel area PXA4.

As described above, the third power line PL3, the second scan line S2i, and the emission control line Ei included in the first conductive layer GAT1 and the fourth scan line S4i, the first scan line S1i, and the third scan line S3i included in the fourth conductive layer GAT2 that may be configured with a different metal material from the first conductive layer GAT1 may be alternately disposed along the second direction DR2. Therefore, the interval between the signal line and/or the power line may be minimized or at least reduced. Thus, a design easiness may be ensured.

A fourth insulating layer ILD4 may be disposed on the fourth conductive layer GAT2 and a fifth conductive layer SD1 may be disposed on the fourth insulating layer ILD4.

Further, as illustrated in FIG. 9, the fifth conductive layer SD1 may include a fourth power line PL4 and a fifth power line PL5 that extend along the first direction DR1 on the center area CA. According to example embodiments, the fourth power line PL4 may include a first sub power line PL4a, a second sub power line PLAb, and a third sub power line PLAc and the fifth power line PL5 may include a fourth sub power line PL5a and a fifth sub power line PL5b. According to example embodiments, the first sub power line PLAa and the third sub power line PLAc may be fourth power lines PL4 that supply the second initialization voltage VAR to a red pixel and a blue pixel and the second sub power line PLAb may be a fourth power lines PL4 that supply the second initialization voltage VAR to a green pixel. This is illustrative, and example embodiments of the present disclosure are not limited thereto. Further, the fourth sub power line PL5a may be a fifth power line PL5 configured to supply the bias voltage VOBS to the first pixel PX1 and the second pixel PX2 and the fifth sub power line PL5b may be a fifth power line PL5 configured to supply the bias voltage VOBS to the third pixel PX3 and the fourth pixel PX4. However, this is illustrative, and the example embodiments of the present disclosure are not limited thereto.

In one example embodiment, the fourth sub power line PL5a, the first sub power line PL4a, the second sub power line PLAb, the third sub power line PLAc, and the fifth sub power line PL5b extend in the first direction DR1, respectively, and may be sequentially disposed along the second direction DR2, on the center area CA.

Here, except a vertical line (for example, as a wiring line that extends along the second direction DR2, a data line Dj included in the sixth conductive layer SD2 and a first power line PL1 configured to supply the first power voltage VDD), only the fourth power line PLA and the fifth power line PL5 that are substantially included in the fifth conductive layer SD1 and extend along the first direction DR1 are disposed in the center area CA excluding the first to fourth pixel areas PXA1 to PXA4, of the pixel area PXA. Therefore, a space for placing another element (for example, stage transistors included in the gate driver GD) may be ensured on the gate area GIA corresponding to the center area CA, of the driving layer DRL that is disposed on the same layer as the pixel circuit layer DSL. Therefore, transistors and capacitors that configure the gate driver GD may be disposed on the gate area GIA of the driving layer DRL.

With reference to FIG. 10 again, the first planarization layer PNL1 may be disposed on the fifth conductive layer SD1 and the sixth conductive layer SD2 may be disposed on the first planarization layer PNL1.

In the meantime, as described with reference to FIG. 8, at least a part of the sixth conductive layer SD2 may configure a data line Dj extending along the second direction DR2.

The second planarization layer PNL2, the seventh conductive layer SD3, the third planarization layer PNL3, the light emitting diode LD, and the encapsulation layer may be sequentially disposed on the sixth conductive layer SD2.

As described above, in the display device according to the example embodiments of the present disclosure, a display panel may include a pixel circuit layer in which a pixel is disposed and a driving layer in which a gate driver is disposed. Here, a gate area in which various elements configuring the gate driver are disposed may be disposed to overlap at least a part of an active area in which various elements configuring the pixel are disposed. For example, transistors included in the driving layer may be disposed on the same layer as at least a part of the transistor included in the pixel circuit layer. For example, the gate driver may be disposed and formed on a gate area overlapping the active area, on the same layer as the pixel circuit layer in which a pixel is disposed, in a gate in array (GIA) manner so that a bezel area of the display device may be minimized or at least reduced.

As compared with the gate in panel (GIP) manner in which the gate driver is formed at the outside of the active area to supply a gate signal to the pixels, in the display device according to the example embodiments of the present disclosure, the gate driver is disposed in at least partial area of the active area, for example, on the gate area, in the gate in array (GIA) manner. Therefore, the gate signal delay according to the relative position of the pixel is minimized or at least reduced to improve the luminance uniformity of the entire active area so that the display device with a high resolution and a large area can be implemented.

Further, in the display device according to the example embodiments of the present disclosure, a seventh conductive layer disposed above the second planarization layer is disposed in a part of a fifth conductive layer that configures a clock line supplying a clock signal to the gate driver and an anode electrode of the light emitting diode to perform a function as a shielding pattern that shields a signal. Therefore, a display quality may be improved.

Further, a pixel included in the display device according to the example embodiments of the present disclosure has a vertical flip structure. Therefore, a space for disposing a transistor and a capacitor that configure the gate driver may be ensured on the gate area of the driving layer which overlaps a center area of the pixel circuit layer.

Further, in the display device according to the example embodiments of the present disclosure, a third power line, a second scan line, and an emission line that are included in a first conductive layer and a fourth scan line, a first scan line, and a third scan line included in a fourth conductive layer that is formed of a different metal material from the first conductive layer are alternately disposed along one direction (a second direction). Therefore, an interval between each signal line and/or a power line may be minimized or at least reduced, and a design easiness may be ensured.

The example embodiments of the present disclosure can also be described as follows:

According to an aspect embodiment of the present disclosure, a display device may include a display panel including a plurality of pixels; and a data driver circuit configured to supply a data signal to the plurality of the pixels through data lines. A gate driver circuit, configured to supply a gate signal to the plurality of the pixels through gate lines, may be disposed in the display panel. The display panel may include: a driving layer including a gate area having the gate driver circuit; and a pixel circuit layer including an active area having a pixel area in which each of the plurality of pixels is disposed and a non-active area around the active area. The pixel circuit layer may include a light emitting diode, a clock line configured to supply a clock signal to the gate driver circuit, and a shielding pattern between the light emitting diode and the clock line.

The pixel area may include a first pixel area in which a first pixel among the plurality of pixels is disposed, a second pixel area in which a second pixel is disposed, a third pixel area in which a third pixel is disposed, a fourth pixel area in which a fourth pixel is included, and a center area that overlaps the gate area.

The second pixel area may be adjacent to the first pixel area along a first direction, the third pixel area is spaced apart from the first pixel area with a predetermined interval along a second direction that is different from the first direction, and the fourth pixel area is adjacent to the third pixel area along the first direction and is spaced apart from the second pixel area with the predetermined interval along the second direction.

The center area may be at an area between the first pixel area and the third pixel area and an area between the second pixel area and the fourth pixel area.

At least one pixel among the plurality of pixels may be connected to each of first to fourth scan lines, an emission control line, a data line, and first to fifth power voltage lines. The first to fourth scan lines, the emission control line, and third to fifth power voltage lines may extend along the first direction to be spaced apart from each other. The data line and the first power voltage line may extend along the second direction.

On the first pixel area and the second pixel area, the third power voltage line, the fourth scan line, the second scan line, the first scan line, the emission control line, and the third scan line may be sequentially disposed to be spaced apart from each other along the second direction and on the third pixel area and the fourth pixel area, the third scan line, the emission control line, the first scan line, the second scan line, the fourth scan line, and the third power voltage line are sequentially disposed to be spaced apart from each other along the second direction.

The fourth power voltage line may include first to third sub power voltage lines and the fifth power voltage line may include fourth and fifth sub power voltage lines, and, on the center area, the fourth sub power voltage line, the first sub power voltage line, the second sub power voltage line, the third sub power voltage line, and the fifth sub power voltage line are sequentially disposed to be spaced apart from each other along the second direction.

The first pixel and the second pixel may be symmetric to each other with respect to the second direction, the third pixel and the fourth pixel are symmetric to each other with respect to the second direction, the first pixel and the third pixel are symmetric to each other with respect to the first direction, and the second pixel and the fourth pixel are symmetric to each other with respect to the first direction.

The pixel circuit layer may include a display element layer having at least one first type transistor, at least one second type transistor, and at least one capacitor; and a light emitting diode layer having the light emitting diode.

The first type transistor may include a polysilicon semiconductor layer and the second type transistor may include an oxide semiconductor layer.

The display element layer may include a first buffer layer, a first semiconductor layer on the first buffer layer and including a first semiconductor pattern of the first type transistor, a first gate insulating layer on the first semiconductor layer, a first conductive layer on the first gate insulating layer and including a first gate electrode of the first type transistor, a first insulating layer on the first conductive layer, a second conductive layer on the first insulating layer, a second insulating layer on the second conductive layer, a third conductive layer on the second insulating layer and including a first source electrode and a first drain electrode of the first type transistor; and a third insulating layer on the third conductive layer.

The display element layer may further include a second buffer layer on the third insulating layer, a second semiconductor layer on the second buffer layer and including a second semiconductor pattern of the second type transistor, a second gate insulating layer on the second semiconductor layer, a fourth conductive layer on the second gate insulating layer and including a second gate electrode of the second type transistor, a fourth insulating layer on the fourth conductive layer, and a fifth conductive layer on the fourth insulating layer and including a second source electrode and a second drain electrode of the second type transistor.

The fifth conductive layer further may include the clock line.

The display element layer may further include a first planarization layer on the fifth conductive layer, a sixth conductive layer on the first planarization layer, a second planarization layer on the sixth conductive layer, and a seventh conductive layer on the second planarization layer. The seventh conductive layer may include the shielding pattern.

A width of the shielding pattern may be larger than a width of an anode electrode of the light emitting diode.

Each of the plurality of pixels may include a driving transistor, a second transistor, a third transistor, and a fourth transistor each including a polysilicon semiconductor layer and a first transistor, a fifth transistor, a sixth transistor, and a seventh transistor each including an oxide semiconductor layer, and each of the plurality of transistors included in the gate driver circuit may include the polysilicon semiconductor layer.

Each of the plurality of pixels may include a light emitting diode; a driving transistor connected between a first node and a second node and configured to generate a driving current flowing from a first power line to supply a first power voltage to a second power line to supply a second power voltage through the light emitting diode; a first transistor connected between the second node and a third node corresponding to a gate electrode of the driving transistor and configured to turn on in response to a first scan signal supplied to a first scan line; a second transistor connected between a data line and the first node and configured to turn on in response to a second scan signal supplied to a second scan line; a third transistor connected between the first power line and the first node and configured to turn off in response to an emission control signal supplied to an emission control line; a fourth transistor connected between the second node and a fourth node corresponding to a first electrode of the light emitting diode and configured to turn off in response to the emission control signal; and a fifth transistor connected between the third node and a third power line configured to supply a third power voltage and configured to turned on in response to a fourth scan signal supplied to a fourth scan line; a sixth transistor connected between the fourth node and a fourth power line configured to supply a fourth power voltage and configured to turn on in response to a third scan signal supplied to a third scan line; a seventh transistor connected between the first node and a fifth power line configured to supply a fifth power voltage and configured to turn on in response to the third scan signal; and a storage capacitor connected between the first power line and the third node.

The driving transistor, the second transistor, the third transistor, and the fourth transistor include a polysilicon semiconductor layer and the first transistor, the fifth transistor, the sixth transistor, and the seventh transistor may include an oxide semiconductor layer.

The driving layer and the pixel circuit layer may be disposed on the same layer.

The display panel may include a plurality of first type transistors and a plurality of second type transistors, and at least some of the plurality of first type transistors may be included in the pixel circuit layer and remaining ones of the plurality of first type transistors may be included in the driving layer.

The plurality of pixels may be directly over the gate driving circuit in a plan view of the display panel.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a display panel including a plurality of pixels; and
a data driver circuit configured to supply a data signal to the plurality of the pixels through data lines;
wherein a gate driver circuit, configured to supply a gate signal to the plurality of the pixels through gate lines, is disposed in the display panel,
wherein the display panel includes:
a driving layer including a gate area having the gate driver circuit; and
a pixel circuit layer including an active area having a pixel area in which each of the plurality of pixels is disposed and a non-active area around the active area, and
wherein the pixel circuit layer includes a light emitting diode, a clock line configured to supply a clock signal to the gate driver circuit, and a shielding pattern between the light emitting diode and the clock line.

2. The display device according to claim 1, wherein the pixel area includes a first pixel area in which a first pixel among the plurality of pixels is disposed, a second pixel area in which a second pixel is disposed, a third pixel area in which a third pixel is disposed, a fourth pixel area in which a fourth pixel is included, and a center area which overlaps the gate area.

3. The display device according to claim 2, wherein the second pixel area is adjacent to the first pixel area along a first direction, the third pixel area is spaced apart from the first pixel area with a predetermined interval along a second direction which is different from the first direction, and the fourth pixel area is adjacent to the third pixel area along the first direction and is spaced apart from the second pixel area with the predetermined interval along the second direction.

4. The display device according to claim 3, wherein the center area is at an area between the first pixel area and the third pixel area and an area between the second pixel area and the fourth pixel area.

5. The display device according to claim 3, wherein at least one pixel among the plurality of pixels is connected to each of first to fourth scan lines, an emission control line, a data line, and first to fifth power voltage lines,
wherein the first to fourth scan lines, the emission control line, and third to fifth power voltage lines extend along the first direction to be spaced apart from each other, and
wherein the data line and the first power voltage line extend along the second direction.

6. The display device according to claim 5, wherein, on the first pixel area and the second pixel area, the third power voltage line, the fourth scan line, the second scan line, the first scan line, the emission control line, and the third scan line are sequentially disposed to be spaced apart from each other along the second direction, and
wherein, on the third pixel area and the fourth pixel area, the third scan line, the emission control line, the first scan line, the second scan line, the fourth scan line, and the third power voltage line are sequentially disposed to be spaced apart from each other along the second direction.

7. The display device according to claim 5, wherein the fourth power voltage line includes first to third sub power voltage lines, and the fifth power voltage line includes fourth and fifth sub power voltage lines, and
wherein, on the center area, the fourth sub power voltage line, the first sub power voltage line, the second sub power voltage line, the third sub power voltage line, and the fifth sub power voltage line are sequentially disposed to be spaced apart from each other along the second direction.

8. The display device according to claim 3, wherein the first pixel and the second pixel are symmetric to each other with respect to the second direction, the third pixel and the fourth pixel are symmetric to each other with respect to the second direction, the first pixel and the third pixel are symmetric to each other with respect to the first direction, and the second pixel and the fourth pixel are symmetric to each other with respect to the first direction.

9. The display device according to claim 1, wherein the pixel circuit layer includes:
a display element layer having at least one first type transistor, at least one second type transistor, and at least one capacitor; and
a light emitting diode layer having the light emitting diode.

10. The display device according to claim 9, wherein the first type transistor includes a polysilicon semiconductor layer, and the second type transistor includes an oxide semiconductor layer.

11. The display device according to claim 9, wherein the display element layer includes:
a first buffer layer;
a first semiconductor layer on the first buffer layer and including a first semiconductor pattern of the first type transistor;
a first gate insulating layer on the first semiconductor layer;
a first conductive layer on the first gate insulating layer and including a first gate electrode of the first type transistor;
a first insulating layer on the first conductive layer;
a second conductive layer on the first insulating layer;
a second insulating layer on the second conductive layer;
a third conductive layer on the second insulating layer, and including a first source electrode and a first drain electrode of the first type transistor; and
a third insulating layer on the third conductive layer.

12. The display device according to claim 11, wherein the display element layer further includes:
a second buffer layer on the third insulating layer;
a second semiconductor layer on the second buffer layer and including a second semiconductor pattern of the second type transistor;
a second gate insulating layer on the second semiconductor layer;
a fourth conductive layer on the second gate insulating layer and including a second gate electrode of the second type transistor;
a fourth insulating layer on the fourth conductive layer; and
a fifth conductive layer on the fourth insulating layer, and including a second source electrode and a second drain electrode of the second type transistor.

13. The display device according to claim 12, wherein the fifth conductive layer further includes the clock line.

14. The display device according to claim 12, wherein the display element layer further includes:
a first planarization layer on the fifth conductive layer;
a sixth conductive layer on the first planarization layer;
a second planarization layer on the sixth conductive layer; and
a seventh conductive layer on the second planarization layer, the seventh conductive layer including the shielding pattern.

15. The display device according to claim 14, wherein a width of the shielding pattern is larger than a width of an anode electrode of the light emitting diode.

16. The display device according to claim 1, wherein each of the plurality of pixels includes a driving transistor, a second transistor, a third transistor, and a fourth transistor each including a polysilicon semiconductor layer and a first transistor, a fifth transistor, a sixth transistor, and a seventh transistor each including an oxide semiconductor layer, and each of the plurality of transistors included in the gate driver circuit includes the polysilicon semiconductor layer.

17. The display device according to claim 1, wherein each of the plurality of pixels includes:
a light emitting diode;
a driving transistor, connected between a first node and a second node, configured to generate a driving current flowing from a first power line to supply a first power voltage to a second power line to supply a second power voltage through the light emitting diode;
a first transistor connected between the second node and a third node corresponding to a gate electrode of the driving transistor, the first transistor being configured to turn on in response to a first scan signal supplied to a first scan line;
a second transistor connected between a data line and the first node, the second transistor being configured to turned on in response to a second scan signal supplied to a second scan line;
a third transistor connected between the first power line and the first node, the third transistor being configured to turn off in response to an emission control signal supplied to an emission control line;
a fourth transistor connected between the second node and a fourth node corresponding to a first electrode of the light emitting diode, the fourth transistor being configured to turn off in response to the emission control signal; and
a fifth transistor connected between the third node and a third power line configured to supply a third power voltage, the fifth transistor being configured to turn on in response to a fourth scan signal supplied to a fourth scan line;
a sixth transistor connected between the fourth node and a fourth power line configured to supply a fourth power voltage, the sixth transistor being configured to turn on in response to a third scan signal supplied to a third scan line;
a seventh transistor connected between the first node and a fifth power line configured to supply a fifth power voltage, the seventh transistor being configured to turn on in response to the third scan signal; and
a storage capacitor connected between the first power line and the third node.

18. The display device according to claim 17, wherein the driving transistor, the second transistor, the third transistor, and the fourth transistor include a polysilicon semiconductor layer and the first transistor, the fifth transistor, the sixth transistor, and the seventh transistor include an oxide semiconductor layer.

19. The display device according to claim 1, wherein the driving layer and the pixel circuit layer are disposed on the same layer.

20. The display device according to claim 1, wherein the display panel includes a plurality of first type transistors and a plurality of second type transistors, and wherein at least some of the plurality of first type transistors are included in the pixel circuit layer and remaining ones of the plurality of first type transistors are included in the driving layer.
